(19) United States
(12) Patent Application Publication
(10) Pub. No.: US 2026/0059729 A1
(43) Pub. Date: Feb. 26, 2026

(54) PROTECTIVE ELEMENT, ENERGY SUPPLY SYSTEM, COMMUNICATIONS SYSTEM, AND MOTOR VEHICLE

(71) Applicant: ElringKlinger AG, Dettingen (DE)

(72) Inventor: Fabian ALBRECHT, Dettingen (DE)

(73) Assignee: ElringKlinger AG, Dettingen (DE)

(21) Appl. No.: 19/374,790

(22) Filed: Oct. 30, 2025

Related U.S. Application Data
(63) Continuation of application No. PCT/EP2024/062212, filed on May 3, 2024.

(30) Foreign Application Priority Data
May 5, 2023 (DE) 10 2023 111 773.4

(51) Int. Cl. H05K 9/00

(52) U.S. Cl. CPC H05K 9/0007; H05K 9/0081

(57) ABSTRACT

A protective element for improving electromagnetic compatibility. The protective element comprises at least a shielding layer for protection from electric, magnetic, and/or electromagnetic fields.

### RELATED APPLICATION

This application is a continuation of international application No. PCT/EP2024/062212 filed on May 3, 2024, and claims the benefit of German application No. 10 2023 111 773.4 filed on May 5, 2023, which are incorporated herein by reference in their entirety and for all purposes.

### FIELD OF DISCLOSURE

The present invention relates to the technical area of protective elements for improving electromagnetic compatibility.

Electromagnetic compatibility (EMC) refers to the freedom from interference of electrical or electronic devices with their surroundings.

### BACKGROUND

Modern motor vehicles are at least partially electrically driven. For this purpose, in addition to high-performance electrochemical energy storage devices, among other things, inverters and electric motors used to drive or accelerate the motor vehicle are installed in the motor vehicles. The various components are connected to one another via power cables.

The direct current provided by the electrochemical energy storage device is convertible into alternating current using an inverter. Inverters are also referred to as converters.

Modern motor vehicles therefore comprise strong sources of electric, magnetic, or electromagnetic fields.

In addition, devices communicating via electric, magnetic, or electromagnetic signals or electromagnetic waves are being integrated more and more into motor vehicles or used by vehicle occupants in motor vehicles.

Ensuring the EMC has thus become a growing challenge. This is to be enabled with the lowest possible component weights, so that the weight of the motor vehicle is not increased or is only increased to a minor extent as much as possible.

### SUMMARY OF THE INVENTION

The present invention is based on the object of providing an effective protective element, an effective energy supply system, an effective communication system, and an effective and reliable motor vehicle with low expenditure. In particular, the most flexible possible utilization of existing installation space is to be enabled in the production of a motor vehicle. In particular, having to take little consideration of the electromagnetic compatibility of various components of an energy supply system and a communication system of a motor vehicle is to be enabled in this case.

The object is achieved according to the invention by the protective element according to the independent claim in this regard.

The protective element is a protective element for improving electromagnetic compatibility, wherein the protective element comprises a shielding layer for protection from electric, magnetic, or electromagnetic fields.

The shielding layer can be, for example, a first shielding layer. When reference is made herein to a first shielding layer or the first shielding layer, this can thus mean the shielding layer.

The protective element can be, for example, a protective element for improving electromagnetic compatibility, wherein the protective element comprises a shielding layer, for example, a first shielding layer, for protection from electric, magnetic, or electromagnetic fields and a second shielding layer for protection from electric, magnetic, or electromagnetic fields.

When reference is made herein to a shielding layer or the shielding layer, this can thus mean the first shielding layer in particular.

Insofar as it is not explicitly indicated otherwise herein and insofar as nothing different results from the context, the designations “a first shielding layer” and “a shielding layer” can preferably be synonymous and exchangeable.

Insofar as it is not explicitly indicated otherwise herein and insofar as nothing different results from the context, the designations “the first shielding layer” and “the shielding layer” can preferably be synonymous and exchangeable.

The protective element can be capable of improving electromagnetic compatibility.

The protective element can be used to improve electromagnetic compatibility.

The protective element can in particular be a protective element to improve electromagnetic compatibility at close range (wavelength in the meter range).

The term “in particular” is used in the scope of this description and the appended claims to describe possibly facultative and/or optional features.

The electric, magnetic, or electromagnetic fields can be, for example, electric, magnetic, or electromagnetic fields which are characteristic for electromagnetic radiation. The electric, magnetic, or electromagnetic fields can be electric, magnetic, or electromagnetic fields of electromagnetic waves or electromagnetic radiation.

The shielding layer can be a shielding layer for protection from electromagnetic radiation.

The first shielding layer can be a first shielding layer for protection from electromagnetic radiation.

The second shielding layer can be a second shielding layer for protection from electromagnetic radiation.

Shielding layers used for protection from electric, magnetic, or electromagnetic fields, in particular shielding layers capable of shielding electromagnetic radiation, are known to those skilled in the art from the technical area of electromagnetic compatibility.

It can be advantageous if the protective element comprises a contacting zone, wherein it can be advantageous if an electrical contact can be established by means of the contacting zone between the shielding layer and a device, on which the protective element can be attached, for example, installed.

It can be advantageous if the protective element comprises a second shielding layer for protection from electric, magnetic, or electromagnetic fields.

It can be advantageous if an electrical contact can be established by means of the contacting zone between the shielding layer of the protective element and/or at least one of the shielding layers of the protective element and a device, on which the protective element can be attached, for example, installed.

It can be advantageous if the contacting zone is a surface of the shielding layer and/or a surface of at least one of the shielding layers; and/or the contacting zone is located at a surface of the shielding layer and/or at a surface of at least one of the shielding layers; and/or the contacting zone is an outer surface contacting zone, wherein the outer surface contacting zone is formed at an outer surface of the shielding layer and/or at an outer surface of at least one of the shielding layers.

It can be advantageous if the protective element comprises a contacting element, wherein it can be advantageous if
an electrical contact, in particular a direct or indirect electrical contact, can be established or stabilized between the contacting zone and the device by means of the contacting element, and/or
an electrical contact bridged by the contacting element can be established between the contacting zone and the device, wherein it can be advantageous if a surface of the contacting element is in electrically conductive contact with the contacting zone, and a further surface of the contacting element can be brought into electrically conductive contact with the device, wherein the contacting element is electrically conductive.

It can be advantageous if the contacting element is deformable and/or elastic.

It can be advantageous if the contacting element is arranged on a carrier, wherein the carrier can preferably be deformable and/or elastic, wherein it can be advantageous if the contacting element extends in at least one section of the carrier from an inner side and/or protective element side of the carrier, which can in particular be facing toward the contacting zone, up to an outer side and/or device side of the carrier, which can in particular be facing away from the contacting zone.

It can be advantageous if the contacting element contains an electrically conductive material or is produced therefrom, wherein the electrically conductive material can preferably be a metallic material, which can in particular contain aluminum. The electrically conductive material can be, for example, a metallic foil, a metallic mesh, a metallic net, or a metallic fabric, in particular an aluminum foil, an aluminum mesh, an aluminum net, or an aluminum fabric, wherein the aluminum foil, the aluminum mesh, the aluminum net, or the aluminum fabric preferably contains aluminum in the form of an alloy which contains at least 50 wt. % Al, preferably at least 60 wt. % Al, for example, at least 85 wt. % Al.

It can be advantageous if the contacting element extends in at least one section of the carrier at the carrier on only one side, for example
on an edge side of the carrier which can be facing toward a protective element edge,
on an edge-averted side of the carrier, which can be facing away from a protective element edge, from the inner side and/or protective element side to the outer side and/or device side.

The carrier can preferably have a polygonal, e.g., quadrilateral, round, or oval cross section, wherein the carrier can be rounded at corners. A quadrilateral cross section, in particular a rectangular cross section, having rounded corners can be particularly advantageous.

It can be advantageous if
the protective element includes a seal element and/or includes a seal element receptacle, in which a seal element can be entirely or partially accommodated, wherein it can be advantageous if the protective element includes the seal element and the seal element receptacle, wherein it can be advantageous if the seal element is entirely or partially accommodated in the seal element receptacle and/or extends in the seal element receptacle on the protective element;
and/or
the protective element includes a seal element, which can preferably be a liquid seal.

It can be advantageous if
the seal element includes the contacting element and/or the carrier;
and/or
the carrier is deformable and/or elastic, wherein it can be advantageous if the contacting element is arranged at the deformable and/or elastic carrier;
and/or
the contacting element includes or forms the seal element.

It can be advantageous if the contacting element and/or the carrier is attached in or at the contacting zone, wherein it can be advantageous if the contacting element and/or the carrier is attached in or at the contacting zone so that an electrical contact of the contacting element to the contacting zone exists or can be established or stabilized.

For example, the contacting element and/or the carrier can be attached in or on the contacting zone so that an electrical contact of the contacting element to the contacting zone exists.

It can be advantageous if the contacting element and/or the carrier is attached via a connecting material arranged in a connecting zone in or at the contacting zone.

It can be advantageous if the contacting element and/or the carrier is attached on the contacting zone by means of an auxiliary element, which can be a seal element, for example, so that an electrical contact of the contacting element to the contacting zone exists or can be established or stabilized, wherein it can be advantageous if the auxiliary element is attached on the contacting zone or in another area of the protective element and the contacting element and/or the carrier is attached on the auxiliary element, wherein it can be advantageous if
the auxiliary element is attached via a connecting material arranged in a connecting zone at the contacting zone or in the other area of the protective element;
and/or
the contacting element and/or the carrier is attached via a connecting material arranged in a connecting zone at the auxiliary element.

It can be advantageous if the protective element includes at least two seal elements, wherein
one of the seal elements is one of the seal elements described herein up to this point or hereinafter,
and/or
one of the seal elements is arranged closer to a protective element edge than another one of the seal elements.

It can be advantageous if the carrier and/or the seal element and/or at least one of the seal elements contains an elastic sealing material and/or is produced from an elastic sealing material, wherein it can be advantageous if the elastic sealing material contains or consists of
a natural or synthetic rubber, for example, an ethylene-propylene-diene rubber, a silicone rubber, and/or a fluorine rubber,
a polyurethane,
and/or
an ethylene tetrafluoroethylene.

An ethylene-propylene-diene rubber is also referred to in abbreviated form as EPDM.

The silicone rubber can be, for example, a methyl-vinyl-silicone rubber. The methyl-vinyl-silicone rubber is also referred to in abbreviated form as VMQ.

The fluorine rubber can be, for example, an FPM.

Polyurethane is also referred to in abbreviated form as PU.

Ethylene tetrafluoroethylene is also referred to in abbreviated form as ETFE.

It can be particularly advantageous if the carrier contains an elastic sealing material and/or is produced from an elastic sealing material, wherein it can be advantageous if the elastic sealing material contains or consists of
a natural or synthetic rubber, for example, an ethylene-propylene-diene rubber, a silicone rubber, and/or a fluorine rubber,
a polyurethane,
and/or
an ethylene tetrafluoroethylene.

It can be particularly advantageous if the carrier contains an ethylene-propylene-diene rubber and/or is produced therefrom.

It can be advantageous if the protective element includes a positioning and/or alignment element, which can be or include, for example, a positioning and/or alignment projection, wherein it can be advantageous if
at least one section of the positioning and/or alignment element can be arranged on at least one section of the contacting zone;
and/or
at least one section of the carrier and/or the seal element and/or at least one of the seal elements and/or the contacting element and/or the connecting zone extends along at least one section of the positioning and/or alignment element.

It can be advantageous if the protective element includes a base body, for example, a plastic base body, wherein
the shielding layer is arranged on the base body, for example, the plastic base body, and/or extends through the base body, for example, the plastic base body,
and/or
at least one of the shielding layers is arranged on the base body, for example, the plastic base body, and/or extends through the base body, for example, the plastic base body.

For example, the shielding layer can extend through the base body, for example, the plastic base body and can extend further up to a surface of the plastic base body and there can form
a contacting zone, for example, an outer surface contacting zone,
and/or
can comprise a bead and/or a raised zone and/or a fold.

The plastic base body can consist of and/or be produced from, for example, a fibrous plastic material.

It can be advantageous if the protective element includes a reinforcement zone, wherein the reinforcement zone includes reinforcement fibers and a fiber connecting material, wherein at least a part of the reinforcement fibers are connected to the fiber connecting material in the reinforcement zone.

It can be advantageous if reinforcement fibers are connected to one another using the fiber connecting material in the reinforcement zone.

It can be advantageous if at least one section of the shielding layer, for example, the first shielding layer, forms a layer composite with at least one section of the reinforcement zone.

It can be advantageous if the at least one section of the shielding layer, for example, the first shielding layer, which forms the layer composite with the at least one section of the reinforcement zone includes the contacting zone.

It can be advantageous if the at least one section of the shielding layer, for example, the first shielding layer, which forms the layer composite with the at least one section of the reinforcement zone, is attached in the layer composite directly to the at least one section of the reinforcement zone.

It can be advantageous if the at least one section of the shielding layer, for example, the first shielding layer, which forms the layer composite with the at least one section of the reinforcement zone is attached indirectly in the layer composite, for example, via at least one intermediate layer, to the at least one section of the reinforcement zone.

It can be advantageous if the protective element is an underbody protective element and/or a battery housing part. It can be particularly advantageous if the protective element is an underbody protective element.

Underbody protective elements are used in particular on motor vehicles for protecting pressurized containers or pressurized tanks and/or electrical components, such as a high-voltage battery device, in particular when driving over bumps, e.g., barriers, bollards, or curbstones.

It can be advantageous if the reinforcement zone is a suspension zone or extends into a suspension zone or extends through a suspension zone.

It can be advantageous if the protective element and/or underbody protective element and/or battery housing part can be attached, for example, installed, in the suspension zone on the device.

The protective element and/or underbody protective element and/or battery housing part can be able to be attached, for example, installed, in the suspension zone on the device by means of an installation recess extending through the suspension zone and a screw or a bolt.

It can be advantageous if a component, for example, a component of a high-voltage battery device, can be attached, for example, installed, on the protective element and/or underbody element and/or battery housing part in the suspension zone.

For example, a component, for example, a component of a high-voltage battery device can be able to be attached, for example, installed, on the protective element and/or underbody protective element and/or battery housing part in the suspension zone by means of an installation recess extending through the suspension zone and a screw or a bolt

It can be advantageous if the protective element and/or underbody protective element and/or battery housing part includes a side wall and an interior, wherein the interior is entirely or partially enclosed by the side wall, wherein the reinforcement zone extends through at least one section of the side wall.

It can be advantageous if a mass proportion of the reinforcement fibers in the reinforcement zone is at least 70%, preferably is at least 72%, particularly preferably is at least 76%, for example, is at least 77.5%.

It can be advantageous if a mass proportion of the reinforcement fibers in the reinforcement zone is at most 90%, preferably is at most 88%, particularly preferably is at most 84%, for example, is at most 82.5%.

It can be particularly advantageous if a mass proportion of the reinforcement fibers in the reinforcement zone is 70% to 90%, preferably is 72% to 88%, particularly preferably is 76% to 84%, for example, is 77.5% to 82.5%.

It can be particularly advantageous if a volume proportion of the reinforcement fibers in the reinforcement zone is at least 70%, preferably is at least 72%, particularly preferably is at least 76%, for example, is at least 77.5%.

It can be advantageous if a volume proportion of the reinforcement fibers in the reinforcement zone is at most 90%, preferably is at most 88%, particularly preferably is at most 84%, for example, is at most 82.5%.

It can be particularly advantageous if a volume proportion of the reinforcement fibers in the reinforcement zone is 70% to 90%, preferably is 72% to 88%, particularly preferably is 76% to 84%, for example, is 77.5% to 82.5%.

A tensile modulus of elasticity of the protective element in the reinforcement zone can advantageously be at least 40 GPa, preferably can be at least 42 GPa, particularly preferably can be at least 44 GPa, for example, can be at least 47 GPa. It has been shown that such high rigidities can in particular be achieved using the high mass proportions of the reinforcement fibers in the reinforcement zone mentioned herein.

A tensile modulus of elasticity of the protective element in the reinforcement zone can advantageously be at most 300 GPa, preferably can be at most 200 GPa, particularly preferably can be at most 150 GPa, for example, can be at most 130 GPa.

For example, a tensile modulus of elasticity of the protective element in the reinforcement zone can be 40 GPa to 300 GPa, preferably can be 42 GPa to 200 GPa, particularly preferably can be 44 GPa to 150 GPa, for example, can be 47 GPa to 130 GPa.

The tensile modulus of elasticity is also known as the modulus of elasticity or Young's modulus. It is used in component testing in order to assess the rigidity of a material or component. It is defined as the ratio of tension to elongation in the elastic range of the material. The tensile modulus of elasticity indicates how strongly a material reacts to tensile load and how much it deforms under tension.

The values mentioned herein for the tensile modulus of elasticity are in particular values measurable at 20° C. The tensile modulus of elasticity can in particular be ascertained or ascertainable according to DIN EN ISO 527-4:2023 or, in particular with only unidirectional reinforcement, according to DIN EN ISO 527-5:2021.

The reinforcement fibers can be or contain mineral fibers, in particular glass fibers or basalt fibers, carbon fibers or polymer fibers, in particular polyamide fibers, for example, aramid fibers.

It can be advantageous if the reinforcement fibers are glass fibers.

A mass proportion of the reinforcement fibers in the reinforcement zone can be determined as follows:

1. Sample taking: A representative sample of the material from which the reinforcement zone is formed is taken from the protective element. It is ensured here that the sample uniformly contains reinforcement fibers and fiber connecting material.

2. Drying: The sample is thoroughly dried in order to remove any moisture which could influence the result. This can be carried out by air drying or the use of a drying furnace.

3. Total mass determination. The dry sample is weighed on a precision balance to determine its total mass.

4. Removal of the fiber connecting material: To separate the reinforcement fibers from the fiber connecting material, a chemical method can be used. For example, the chemical method can be a combustion or a pyrolysis of the fiber connecting material. Combustion is suitable in particular if the reinforcement fibers are mineral fibers, such as glass fibers or basalt fibers. Pyrolysis is suitable in particular if the reinforcement fibers are carbon fibers.

5. Determining the fiber mass: The mass of the reinforcement fibers remaining after the chemical method is determined on a precision balance.

6. Calculating the mass proportion: The mass of the reinforcement fibers is divided by the total mass and the result is multiplied by 100 to obtain the mass proportion of the reinforcement fibers in percent.

A volume proportion of the reinforcement fibers in the reinforcement zone can be determined as follows:

1. Sample taking: A representative sample of the material from which the reinforcement zone is formed is taken from the protective element. It is ensured here that the sample uniformly contains reinforcement fibers and fiber connecting material.

2. Producing sections: Sections are created in different sectioning directions.

3. Ascertaining total sectional area: The total sectional area of the created sectional surfaces is calculated.

4. Ascertaining fiber sectional area: The sectional area occupied as a whole by the reinforcement fibers within the sections is ascertained by microscopy.

5. Calculating the volume proportion: The fiber sectional area is divided by the total sectional area and the result is multiplied by 100 to obtain the volume proportion of the reinforcement fibers in percent.

It can be advantageous if the reinforcement zone includes a fiber laying and/or the reinforcement fibers, for example, the glass fibers, are aligned unidirectionally in at least one layer of the reinforcement zone.

The fiber laying can contain glass fibers.

The fiber laying can be, for example, a glass fiber laying.

It can be advantageous if the reinforcement fibers, for example, the glass fibers, are aligned unidirectionally in at least one further layer of the reinforcement zone, wherein the alignment of the reinforcement fibers, for example, the glass fibers, in the at least one further layer of the reinforcement zone differs from the alignment of the reinforcement fibers, for example, the glass fibers, in the at least one layer of the reinforcement zone.

For example, the alignment of the reinforcement fibers in the one layer can occupy an angle in relation to the alignment of the reinforcement fibers in the further layer of at least 2°, preferably at least 4°, particularly preferably at least 10°, very particularly preferably at least 20°, in particular at least 30°, for example, at least 45°.

It can be advantageous if the reinforcement zone includes multiple UD tape layers.

The term “UD tape layer” can in particular mean a layer of the reinforcement zone which is produced from a UD tape.

The term “UD tape” is known to those skilled in the art. UD tapes enable the lightweight construction of high-strength structural elements with high material efficiency.

Unidirectional tapes, also called UD tapes, are endless fiber-reinforced bands of different width having unidirectionally aligned reinforcement fibers.

It can be advantageous if the tensile modulus of elasticity is a tensile modulus of elasticity measurable in the fiber direction.

It can be advantageous if the fiber connecting material contains a thermoplastic material and/or is produced from a thermoplastic material.

It can be advantageous if the melt mass flow rate (also referred to in abbreviated form, for example, as MFR, colloquially, for example, also as MFI) of the fiber connecting material is at least 50 g/10 minutes, in particular at least 100 g/10 minutes, preferably at least 200 g/10 minutes, particularly preferably at least 400 g/10 minutes, very particularly preferably at least 650 g/10 minutes, for example, at least 1100 g/10 minutes.

It can be advantageous if the melt mass flow rate of the fiber connecting material is at most 10 000 g/10 minutes, in particular at most 5000 g/10 minutes, preferably at most 4500 g/10 minutes, particularly preferably at most 4000 g/10 minutes, very particularly preferably at most 3500 g/10 minutes, for example, at most 3200 g/10 minutes.

It can be particularly advantageous if the melt mass flow rate of the fiber connecting material is 50 g/10 minutes to 10 000 g/10 minutes, in particular 100 g/10 minutes to 5000 g/10 minutes, preferably 200 g/10 minutes to 4500 g/10 minutes, particularly preferably 400 g/10 minutes to 4000 g/10 minutes, very particularly preferably 650 g/10 minutes to 3500 g/10 minutes, for example, 1100 g/10 minutes to 3200 g/10 minutes.

The thermoplastic material can preferably be a thermoplastic copolymer or homopolymer material.

The thermoplastic material can be, for example, a polyolefin material, preferably a polypropylene material.

Many different commercially-available thermoplastic materials come into consideration for the production and/or as a component of the thermoplastic material. In particular, many different commercially-available polymers and thermoplastic materials have melt mass flow rates within the range limits mentioned herein.

A good impregnation could be rapidly achieved in the reinforcement zone, even with the high mass proportions and/or volume proportions of reinforcement fibers specified herein, in particular if a thermoplastic material having high MFR was used as the fiber connecting material.

However, it has been observed that surfaces of the reinforcement zone then appeared less homogeneous and individual fibers were sometimes clearly recognizable.

It has been shown that sealing materials which were pressed thereon could not always reliably provide desired sealing effects. The challenge resulted therefrom of being able to achieve the desired sealing effect with higher reliability using typical sealing materials even directly at reinforcement zones.

It has also been shown that routine UD tapes are produced with matrix systems or fiber connecting materials which sink less strongly into the tape interior and form more of a closed tape surface. Therefore, components or protective elements which are produced using such tapes have a significantly more homogeneous surface having less roughness. This better surface quality is purchased with these UD tapes at the cost of a poor through impregnation of the tapes, however, which is significantly reflected in the mechanical properties, above all in the case of impact loads. This property reduction is not desired and/or not permissible in impact-loaded components, for example, in underbody protective elements.

It can be advantageous if the protective element includes a sealing layer, wherein it can be advantageous if at least one section of the sealing layer is arranged at the reinforcement zone and seals at least one section of the reinforcement zone.

The sealing layer can completely or partially fill pores and/or depressions present on a surface of the reinforcement zone and/or can reduce a roughness on the surface of the reinforcement zone, by which desired seal effects on the surface can be achieved with higher reliability. At the same time, a higher resistance to impact loads can be achieved by the fiber connecting material. If the sealing takes place due to the sealing layer, it does not require the fiber connecting material for this purpose. The fiber connecting material can thus penetrate up to a core area of the reinforcement zone and also connect reinforcement fibers there, due to which a resistance to impact loads appears to be able to be increased as a whole.

It can be advantageous if the at least one sealed section of the reinforcement zone is a section of the suspension zone or is the suspension zone and/or extends around the installation recess.

It can be advantageous if the sealing layer does not contain reinforcement fibers or a mass proportion of the reinforcement fibers in the sealing layer is less than the mass proportion of the reinforcement fibers in the reinforcement zone or a volume proportion of the reinforcement fibers in the sealing layer is less than the volume proportion of the reinforcement fibers in the reinforcement zone.

It can be advantageous if the sealing layer contains a sealing plastic and/or consists of a sealing plastic and/or is produced from a sealing plastic. The sealing plastic can contain or be a polyolefin, such as polypropylene.

It can be advantageous if the sealing layer is produced from a plastic film and/or contains a plastic film and/or consists of a plastic film, wherein the plastic film contains a sealing plastic and/or consists of a sealing plastic and/or is produced from a sealing plastic.

The plastic film can preferably be a polyolefin film, for example, a polypropylene film.

The sealing plastic preferably has a melt mass flow rate of less than 50 g/10 minutes, particularly preferably of less than 20 g/10 minutes, very particularly preferably of less than 10 g/10 minutes, for example, of less than 5 g/10 minutes.

If the sealing layer does not contain reinforcement fibers, a mean thickness of the sealing layer can preferably be 10 μm to 500 μm, particularly preferably 25 μm to 400 μm, for example, 30 μm to 250 μm.

The values specified herein for the melt mass flow rate relate to the melt mass flow rate measured according to ISO 1133-1:2012 at 230° C. and 2.16 kg.

If the sealing layer contains reinforcement fibers, the sealing layer can be produced using a tape, in particular UD tape.

If the sealing layer contains reinforcement fibers, the mass proportion of the reinforcement fibers in the reinforcement zone can correspond to at least 1.1 times the mass proportion, preferably at least 1.2 times the mass proportion, of the reinforcement fibers in the sealing layer.

If the sealing layer contains reinforcement fibers, the mass proportion of the reinforcement fibers in the reinforcement zone can correspond to at most 30 times the mass proportion, preferably at most 20 times the mass proportion, of the reinforcement fibers in the sealing layer.

If the sealing layer contains reinforcement fibers, the mass proportion of the reinforcement fibers in the reinforcement zone can correspond to 1.1 times to 30 times the mass proportion, preferably 1.2 times to 20 times the mass proportion, of the reinforcement fibers in the sealing layer.

If the sealing layer contains reinforcement fibers, the volume proportion of the reinforcement fibers in the reinforcement zone can correspond to at least 1.1 times the volume proportion, preferably at least 1.2 times the volume proportion, of the reinforcement fibers in the sealing layer.

If the sealing layer contains reinforcement fibers, the volume proportion of the reinforcement fibers in the reinforcement zone can correspond to at most 30 times the volume proportion, preferably at most 20 times the volume proportion, of the reinforcement fibers in the sealing layer.

If the sealing layer contains reinforcement fibers, the volume proportion of the reinforcement fibers in the reinforcement zone can correspond to 1.1 times to 30 times the volume proportion, preferably 1.2 times to 20 times the volume proportion, of the reinforcement fibers in the sealing layer.

If the sealing layer contains reinforcement fibers, a mean thickness of the sealing layer can preferably be 50 μm to 500 μm, particularly preferably 80 μm to 400 μm, for example, 125 μm to 250 μm.

It can be advantageous if the protective element comprises a shielding zone, in which the first and the second shielding layer are spaced apart from one another.

In the shielding zone, the thickness of all shielding layers together can be, for example, 0.005% to 80% of a mean wall thickness of the protective element. The mean wall thickness of the protective element can be a mean wall thickness in the shielding zone.

The thickness of all shielding layers together can in particular be 0.01% to 50%, preferably 0.05% to 30%, for example, 0.05% to 15%, of this mean wall thickness.

A density of the protective element can preferably be at most 2.0 g/cm³, particularly preferably at most 1.7 g/cm³. The density of the protective element can in particular be in a range from 0.03 g/cm³ to 2.0 g/cm³, for example, in a range from 0.04 g/cm³ to 1.7 g/cm³.

The density of the protective element can in particular be a mean density of the protective element. The mean density can be ascertained from the mass and the volume of the protective element. The volume of the protective element can correspond, for example, to the volume of a liquid, such as water, which is displaced by the protective element upon immersion in the liquid, such as water.

At least one layer of the protective element can be foamed. The at least one foamed layer of the protective element can contain, for example, a foamed plastic.

A particularly low density can be achieved, for example, in that at least one layer of the protective element is foamed and the density of the shielding layer and/or all shielding layers together is as low as possible. This can in particular contribute to a pronounced shielding attenuation being able to be achieved using a particularly light protective element, by which ultimately the effectiveness and the reliability of a motor vehicle can ultimately be increased at the same time.

Surprisingly, it has been shown in experiments, which are described in more detail herein in conjunction with FIGS. 12 to 16, that very pronounced shielding-attenuation effects can be achieved using two shielding layers according to the invention. This is achieved with very low expenditure for shielding material.

In particular in this respect, the protective element according to the invention can be producible effectively and with particularly low expenditure for shielding material.

The number of the shielding layers comprised by the protective element is not restricted to two. For example, the protective element can comprise only one shielding layer or more than two shielding layers.

It can be advantageous if the protective element comprises a third shielding layer for protection from electric, magnetic, or electromagnetic fields.

It can be particularly advantageous if the protective element comprises a fourth shielding layer for protection from electric, magnetic, or electromagnetic fields.

It can be advantageous if in the shielding zone, in which the first and the second shielding layer are spaced apart from one another, the second and the third shielding layer are also spaced apart from one another.

In at least one area of the shielding zone, in which the first and the second shielding layer are spaced apart from one another, a distance between the second and third shielding layer can differ from a distance between the first and second shielding layer.

It can be advantageous if the protective element comprises a reinforcement layer or multiple reinforcement layers, wherein it can be advantageous if the reinforcement layer or at least one of the reinforcement layers contains fibers, for example, glass fibers, in particular in the form of glass fibers contained in unidirectional tapes. In a layer structure of the protective element, the reinforcement layer or at least one of the reinforcement layers can be arranged at least in one section of the protective element closer to an outer surface of the protective element than the shielding layer and/or can be arranged closer to an outer surface of the protective element than at least one of multiple shielding layers of the protective element.

It can be advantageous if an intermediate layer is arranged between the first shielding layer and the second shielding layer.

The intermediate layer can preferably comprise a plastic layer and/or a reinforcement layer.

The intermediate layer can comprise a plastic layer.

The intermediate layer can comprise a reinforcement layer. The reinforcement layer can contain reinforcement elements, such as fibers.

The intermediate layer can comprise a plastic layer and a reinforcement layer.

The term “intermediate layer” can refer herein to a single-ply intermediate layer or to a multi-ply intermediate layer structure.

The intermediate layer can preferably be arranged in the shielding zone between the first shielding layer and the second shielding layer.

If the protective element comprises a third shielding layer for protection from electric, magnetic, or electromagnetic fields, a further intermediate layer can be arranged between the second shielding layer and the third shielding layer. A layer structure of the further intermediate layer can correspond to a layer structure of the intermediate layer or differ from the layer structure of the intermediate layer.

The further intermediate layer can preferably be arranged in the shielding zone between the second shielding layer and the third shielding layer.

The protective element is not restricted with regard to the type and number of the layers. In particular, the protective element can comprise further layers in addition to the mentioned layers.

It can be particularly advantageous if a layer composite zone is present in which the first and the second shielding layer are connected by means of the intermediate layer.

A layer composite zone, in which the first and the second shielding layer are connected by means of the intermediate layer, can advantageously be present in the shielding zone.

The protective element can be a layer composite protective element or a layer composite component.

It can be particularly advantageous if the first shielding layer, the second shielding layer, and the intermediate layer arranged between the first shielding layer and the second shielding layer represent the layer structure or a part of the layer structure of the layer composite protective element or the layer composite component.

The protective element, for example, the layer composite protective element or the layer composite component, can be entirely or partially obtained by compression molding.

The protective element, for example, the layer composite protective element or the layer composite component, can in particular be entirely or partially obtained by a compression molding method, wherein a precursor material of an intermediate layer is arranged between a precursor of a first shielding layer and a precursor of a second shielding layer. The protective element precursor obtained in this case can be converted into the protective element, for example, into the layer composite protective element or the layer composite component.

The protective element, for example, the layer composite protective element or the layer composite component, can be at least partially obtained by injection molding.

The protective element, for example, the layer composite protective element or the layer composite component, can in particular be entirely or partially obtained by an injection molding method, wherein a free-flowing precursor compound of an intermediate layer or a part of an intermediate layer is introduced between a precursor of a first shielding layer and a precursor of a second shielding layer. The protective element precursor obtained in this case can be converted into the protective element, for example, the layer composite protective element or the layer composite component.

The conversion of the protective element precursor into the protective element can take place, for example, in a molding tool, for example, in a compression molding tool or an injection molding tool.

Forming into the protective element, for example, into the layer composite protective element or the layer composite component, can preferably take place in the molding tool. An interior of the protective element described herein and/or a depression of the protective element described herein can be entirely or partially formed in this case.

A shielding layer can differ from other layers or one other layer of the protective element, for example, in that the electrical conductivity of the shielding layer is greater than an electrical conductivity of the other layers or the other layer of the protective element.

It can be particularly advantageous if the shielding layer is electrically conductive and/or the shielding layers are electrically conductive.

When reference is made herein to an electrical conductivity of a shielding layer, this means in particular an electrical conductivity of the shielding layer in the layer plane. The electrical conductivity can exist at least in one direction within the layer plane.

An electrical conductivity of a shielding layer within the layer plane can be at least 5 S/m, preferably at least 20 S/m, for example, at least 100 S/m, in at least one direction.

It can be advantageous if the shielding layer and/or at least one of the shielding layers, for example, the first shielding layer, has a relative permeability μᵣ of at least 10. The relative permeability can preferably be at least 50, particularly preferably at least 250, very particularly preferably at least 1000, for example, at least 5000. The relative permeability Ur can be 10 to 10 000 000, preferably 50 to 2 000 000, particularly preferably 250 to 1 500 000.

It can be advantageous if the relative permeability μᵣ of the first shielding layer is at least 10 times as high, particularly preferably at least 50 times as high, for example, at least 400 times as high as the relative permeability u, of the second shielding layer.

It can be advantageous if the relative permeabilities of the first shielding layer and the second shielding layer behave according to the following formula:

$${μ}_{r} ( 1 ) = k {μ}_{r} ( 2 )$$

in which
μᵣ(1) stands for the relative permeability μᵣ of the first shielding layer,
μᵣ(2) stands for the relative permeability μᵣ of the second shielding layer, and
the factor k can be at least 10, preferably at least 10², particularly preferably at least 10³, very particularly preferably at least 10⁴, for example, at least 10⁵.

A particularly high relative permeability of the first shielding layer can be advantageous. The factor k can in particular be up to 10⁷, preferably up to 5 times 10⁶, particularly preferably up to 2 times 10⁶, very particularly preferably up to 8 times 10⁵, for example, up to 6 times 10⁵.

The factor k can advantageously be in the range of 10 to 10⁷, preferably in the range of 10 to 5 times 10⁶, particularly preferably in the range of 10² to 5 times 10⁶, very particularly preferably in the range of 10³ to 2 times 10⁶, for example, in the range of 10⁴ to 6 times

It can be particularly advantageous if the shielding layer and/or at least one of the shielding layers, for example, the first shielding layer, is ferromagnetic.

The shielding layer and/or at least one of the shielding layers, for example, the first shielding layer, can preferably contain a mu-metal, a permalloy, or a supermalloy or can be formed from a mu-metal, a permalloy, or a supermalloy.

It can be advantageous if the shielding layer and/or at least one of the shielding layers, for example, the first shielding layer, contains a mu-metal or is formed from a mu-metal.

It can be advantageous if the shielding layer and/or at least one of the shielding layers, for example, the first shielding layer, contains a permalloy or is formed from a permalloy.

It can be advantageous if the shielding layer and/or at least one of the shielding layers, for example, the first shielding layer, contains a supermalloy or is formed from a supermalloy.

For specific applications, in which a particularly pronounced shielding-attenuation effect is desired, it has proven to be particularly helpful to embody the shielding layer and/or at least one of the shielding layers so that the relative permeability μᵣ is high, or to produce the at least one shielding layer from a ferromagnetic material, for example, from a mu-metal. It has been established in conjunction with the invention that effective shielding at close range can thus be achieved in particular.

It can be particularly advantageous if the protective element comprises a contact zone, in which the first and the second shielding layer are in electrical contact or in which an electrical contact can be established between the first and the second shielding layer.

The first and the second shielding layer can be in electrical contact in the contact zone. The first and the second shielding layer can be in direct electrical contact in the contact zone. One of the two shielding layers can be led up to the other of the two shielding layers in the contact zone. In the contact zone, a surface of the first shielding layer can extend in contact with a surface of the second shielding layer along the surface of the second shielding layer.

The first and the second shielding layer can be in indirect electrical contact in the contact zone. An electrically conductive connecting element can be provided in the contact zone, which connects the first and the second shielding layer. The electrically conductive connecting element can preferably bridge the first and the second shielding layer across an intermediate layer.

The electrically conductive connecting element can bridge the first and the second shielding layer through the intermediate layer, for example. Alternatively, the electrically conductive connecting element can bridge the first and the second shielding layer at an edge. The edge can be an edge of an intermediate layer or an edge of the protective element, wherein the first and the second shielding layer can preferably extend up to the edge of the protective element.

An electrical contact can be able to be established in the contact zone between the first and the second shielding layer. An electrical contact can preferably be able to be established via an arrangement zone in the contact zone between the first and the second shielding layer. The arrangement zone can be designed, for example, so that an electrically conductive connecting element can be arranged in or at the arrangement zone. The arrangement zone can be, for example, a receptacle zone or can comprise a receptacle zone, wherein the electrically conductive connecting element or a part of the electrically conductive connecting element can be able to be accommodated in the receptacle zone. It can be advantageous if the first shielding layer and the second shielding layer each extend up to the arrangement zone, for example, up to the receptacle zone.

The electrically conductive connecting element described herein can be, for example, a sleeve, a screw, a rivet, a tube, in particular a fully fabric tube, or a sheet-metal part, in particular a sheet-metal part formed by forming a sheet-metal plate.

The protective element preferably comprises a contacting zone.

An electrical contact can be able to be established between the shielding layer and a device by means of the contacting zone, at which the protective element can be attached, for example, installed.

An electrical contact can be able to be established between at least one of the shielding layers of the protective element and a device by means of the contacting zone, at which the protective element can be attached, for example, installed.

An electrical contact can be able to be established between at least one of the shielding layers of the protective element and a device by means of the contacting zone, at which the protective element can be attached, for example, installed.

The contacting zone can preferably be a surface of the shielding layer and/or a surface of at least one of the shielding layers and/or can be located on a surface of the shielding layer and/or on a surface of at least one of the shielding layers.

The electrical contact which can be established between the contacting zone and the device can be a direct electrical contact or an indirect electrical contact between the surface of the at least one shielding layer and the device. If the contact is an indirect contact, the contact can be an electrical contact which can be bridged or is bridged by a bridge element between the at least one shielding layer and the device.

It can be particularly advantageous if the protective element comprises a contacting element.

An electrical contact, in particular a direct or indirect electrical contact, between the contacting zone and the device can preferably be able to be established or stabilized by means of the contacting element.

Preferably, a direct electrical contact between the contacting zone and the device can be able to be established or stabilized by means of the contacting element.

In this case, the contacting element can be pressed in the area of the contacting zone from an inner area of the protective element onto the at least one shielding layer. The at least one shielding layer can thus be supported in the area of the contacting zone from an inner area of the protective element so that an outer surface of the at least one shielding layer, which can be the contacting zone, can be pressed firmly onto the device.

For example, a protrusion element can be pressed onto the shielding layer, so that the contacting zone bulges there, for example, at a point, toward the device, by which a stable electrical contact to the device can be established. The contacting element can then be electrically conductive or electrically insulating. This is because it can promote establishing or stabilizing a direct electrical contact between the at least one shielding layer and the device essentially by way of a supporting effect. The contacting element itself then does not have to conduct electric current.

An electrical contact bridged by the contacting element can preferably be able to be established between the contacting zone and the device. For example, one surface of the contacting element can be in electrically conductive contact with the contacting zone, which can be, for example, a surface of the at least one shielding layer, and a further surface of the contacting element can be able to be brought into electrically conductive contact with the device. The contacting element is then electrically conductive.

The contacting element can preferably be ring-shaped. The ring-shaped contacting element can be a sleeve. Such a shape can be advantageous, since a connecting element, such as a screw, can be led through the opening of the ring-shaped contacting element or the sleeve to fasten the protective element on the device.

Advantageously, at least one part of the contacting element can be connected in a materially bonded manner to the intermediate layer and/or at least one part of the contacting element can be incorporated in the intermediate layer. This can be effectuated in a particularly elegant manner, for example, in that the contacting element is positioned in a molding method at the desired point between the first shielding layer and the second shielding layer, so that a precursor material of the intermediate layer, for example, a plastic material and/or reinforcement material, in particular a plastic melt, can spread around the contacting element and can incorporate the contacting element in the resulting intermediate layer.

Preferably, the shielding layer and/or at least one of the shielding layers can comprise a shielding layer excess.

It can be advantageous if the shielding layer excess comprises the contacting zone.

In particular the area of a shielding layer which protrudes over another layer of the layer structure of the protective element can be understood as the shielding layer excess.

An electrically conductive connecting element, for example, a sleeve, via which an electrical contact is established or can be established in the context zone between the first and the second shielding layer, can advantageously at the same time provide a receptacle for a connecting element, using which the protective element can be attached, for example, installed.

Preferably, the shielding layer and/or the at least one of the shielding layers extends into a contacting zone. The contacting zone can be an outer surface contacting zone.

In the outer surface contacting zone, the shielding layer and/or at least one of the shielding layers can form a cover layer of a multilayer layer structure of the protective element.

The layer which forms a final layer in the layer structure of the protective element is always referred to as the cover layer herein. One of the main surfaces of the cover layer then forms one of the main surfaces of the protective element.

The protective element can preferably comprise an offset zone. At least one of the shielding layers can expand up to the other shielding layer or to another shielding layer in the offset zone. The offset zone can be arranged in a transition from the shielding zone into the contacting zone.

It can be advantageous if at least one of the shielding layers comprises a bead and/or a raised zone and/or a fold. The bead can be a half bead or a full bead. An electrical contact between the first and the second shielding layer can exist via the bead, the raised zone, and/or the fold. Alternatively or additionally, an electrical contact between the shielding layer and a device and/or between at least one of the shielding layers and a device can be able to be established via the bead, the raised zone, and/or the fold in the contacting zone.

It can be particularly advantageous if the shielding layer and/or at least one of the shielding layers, for example, at least the second shielding layer, contains the following:
a metallic alloy, wherein the metallic alloy can be, for example, a metallic alloy based on aluminum, copper, iron, or silver;
a conductive carbon material, wherein the conductive carbon material can contain, for example, carbon fibers or graphite;
a composite made of a metal and a textile material, preferably a metallically coated textile material, wherein the textile material can preferably be a knitted fabric, a woven fabric, a laying, a knit, a mesh, or a nonwoven material, for example, a composite made of an aluminum foil and a PET nonwoven material;
a foil, preferably a metal foil, for example, an aluminum foil;
an expanded metal;
a regular fibrous planar formation, wherein the regular fibrous planar formation can be, for example, a knitted fabric, a woven fabric, a laying, a knit, or a mesh; and/or
an irregular fibrous planar formation, wherein the irregular fibrous planar formation can be, for example, a nonwoven material.

The shielding layer or the shielding layers can each contain at least one of the alternatives listed above independently of one another.

The shielding layer and/or at least one of the shielding layers, for example, at least the second shielding layer, can preferably be provided as
a foil,
a plate,
a regular fibrous planar formation, wherein the regular fibrous planar formation can be, for example, a woven fabric, a laying, or a knit, or as
an irregular fibrous planar formation, wherein the irregular fibrous planar formation can be, for example, a nonwoven material.

The foil can be a metal foil, for example, an aluminum foil . . .

Preferably, the shielding layer and/or at least one of the shielding layers, for example, at least the second shielding layer, can be selected among:
an aluminum foil,
an aluminum mesh,
a stainless-steel mesh,
a bronze mesh,
a copper mesh,
a plastic nonwoven material, (for example, PET nonwoven material), having applied aluminum film,
a plastic nonwoven material (for example, PET nonwoven material), which is coated on one side using copper,
a carbon fiber-containing unidirectional tape,
a nonwoven material made of recycled carbon fibers,
a graphite film, and
a polymer (for example, polypropylene) in a composite with an aluminum mesh.

It can be particularly advantageous if the shielding layer and/or at least one of the shielding layers, for example, at least the second shielding layer, contains a metal, e.g., aluminum, copper, iron and/or silver.

It can be particularly advantageous if the shielding layer and/or at least one of the shielding layers, for example, at least the second shielding layer, contains aluminum.

It can be particularly advantageous if a thickness of the shielding layer and/or at least one of the shielding layers, for example, a thickness of the second shielding layer, is at most 3 mm.

Preferably, the thickness of the shielding layer and/or at least one of the shielding layers, for example, a thickness of the second shielding layer, can be 50 μm to 2.5 mm, particularly preferably 100 μm to 2 mm, very particularly preferably 200 μm to 1.5 mm, for example, 0.001 mm to 0.7 mm.

Preferably, the thickness of the shielding layer and/or at least one of the shielding layers, for example, the thickness of the second shielding layer, can be an average thickness of the respective shielding layer.

It can be advantageous if the thickness of the shielding layer and/or all shielding layers, for example, the thickness of the first shielding layer, the thickness of the second shielding layer, and, if present, the thickness of at least one further shielding layer are each at most 3 mm, preferably 50 μm to 2.5 mm, particularly preferably 100 μm to 2 mm, very particularly preferably 200 μm to 1.5 mm, for example, 0.001 mm to 0.7 mm.

It can be particularly advantageous if the shielding layer and/or at least one of the shielding layers, for example, at least the second shielding layer, is an aluminum foil or an aluminum plate. The thickness of the aluminum foil or the aluminum plate can in particular be 0.02 mm to 1 mm, preferably 0.05 mm to 0.5 mm, particularly preferably 0.1 mm to 0.25 mm, for example, 0.12 mm to 0.18 mm.

Advantageously, the shielding layer and/or at least one of the shielding layers, for example, the first shielding layer, can have a relative permeability μᵣ of at least 10, can be ferromagnetic, and/or can contain a mu-metal or be formed from a mu-metal, and the shielding layer and/or at least one of the shielding layers, for example, at least the second shielding layer, can be a foil, a metal foil, an aluminum foil, a metal plate, or an aluminum plate.

It can be particularly advantageous if the foil, the metal foil, the aluminum foil, the metal plate, or the aluminum plate, for example, the foil, metal foil, or aluminum foil, is attached by means of an adhesion promoter to an adjacent layer. The adjacent layer can be, for example, the intermediate layer, the plastic layer, and/or the reinforcement layer.

It can be advantageous if the shielding layer and/or at least one of the shielding layers is formed on a surface of a substrate layer.

The shielding layer and/or the at least one of the shielding layers can preferably be formed on the surface by deposition from a surrounding medium. The surrounding medium can be a surrounding fluid, for example, a surrounding gas phase.

Methods for depositing layers on surfaces from surrounding media are known to those skilled in the art.

The shielding layer and/or the at least one of the shielding layers can be vapor deposited on the surface, for example.

The substrate layer can be the intermediate layer described herein, for example, a plastic layer which forms the intermediate layer described herein or is contained in the intermediate layer described herein, or a reinforcement layer, which forms the intermediate layer described herein or is contained in the intermediate layer described herein.

The protective element can preferably comprise a protective element surface for attaching the protective element to a device that can be interfered with by electric, magnetic, or electromagnetic fields or to a source of electric, magnetic, or electromagnetic fields.

The protective element can comprise, for example, a protective element surface for attaching the protective element to a device that can be interfered with by electric, magnetic, or electromagnetic fields.

The protective element can comprise, for example, a protective element surface for attaching the protective element to a source of electric, magnetic, or electromagnetic fields.

The protective element can be an immission protective element. The immission protective element can preferably comprise a protective element surface for attaching the immission protective element to a device that can be interfered with by electric, magnetic, or electromagnetic fields.

The protective element can be an emission protective element. The emission protective element can preferably comprise a protective element surface for attaching the emission protective element to a source of electric, magnetic, or electromagnetic fields.

The protective element can have a depression and/or define an interior. The interior can extend in the depression. It can be advantageous if the seal element or the carrier or at least two of the at least two seal elements which the protective element can include extends entirely or partially around the depression. This can contribute to the interior being able to be sealed in relation to the surroundings.

A first extension, for example, length, of the protective element measurable in a first direction can be greater than a second extension, for example, width of the protective element measurable in a second direction, which is aligned orthogonally to the first direction.

A first extension, for example, length, of the protective element measurable in a first direction can be greater than a third extension, for example, depth of the protective element, measurable in a third direction, which is aligned orthogonally to the first direction.

It can be advantageous if the third direction is aligned orthogonally to the first direction and orthogonally to the second direction.

It can be advantageous if the extension measurable in the first direction is 0.7 m to 4.0 m, preferably is 1.0 m to 3.5 m, in particular is 1.2 m to 3.2 m, for example, is 1.5 m to 3.0 m.

It can be advantageous if the extension measurable in the second direction is at most 90% of the extension measurable in the first direction and/or is 0.2 m to 3.0 m, preferably is 0.3 m to 2.8 m, in particular is 0.5 m to 2.6 m, for example, is 0.8 m to 2.3 m.

It can be advantageous if the extension measurable in the third direction is at most 30% of the extension measurable in the first direction and/or is 3 cm to 120 cm, preferably is 4 cm to 100 cm, in particular is 5 cm to 90 cm, for example, is 6 cm to 80 cm.

The protective element surface for attaching the protective element can preferably extend from a protective element edge to a or the depression of the protective element.

The protective element surface can be a surface of a flange.

The protective element surface can include a plurality of contacting zones. Each of the contacting zones can be a contacting zone described herein.

A mean distance of the contacting zones can preferably be in a range from 0.5 cm to 80 cm, particularly preferably in a range from 1 cm to 50 cm, for example, in a range from 1.5 cm to 30 cm.

The depression can extend into an interior of the protective element.

The device that can be interfered with by electric, magnetic, or electromagnetic fields can be able to be accommodated or accommodated entirely or partially in the interior.

The source of electric, magnetic, or electromagnetic fields can be able to be accommodated or accommodated entirely or partially in the interior.

A wall, for example, a side wall of the protective element can extend to the protective element surface. The wall can entirely or partially enclose the interior or extend entirely or partially around the interior.

The protective element can include at least one feedthrough zone.

The feedthrough zone can extend into the interior of the protective element. The feedthrough zone can extend, for example, through the wall, for example, through the side wall, into the interior

The protective element can be a housing element. The protective element can be, for example, an inverter housing element. An inverter can be able to be accommodated or accommodated entirely or partially in the interior.

A cable can extend through a feedthrough zone to the inverter. A cable shield of the cable is preferably connected circumferentially and/or completely and/or uninterruptedly to the shield of the housing.

The object is achieved according to the invention by the energy supply system according to the independent claim in this regard.

The energy supply system can be, for example, an energy supply system for an entirely or partially electrically driven vehicle. In particular, the energy supply system can be designed and configured to entirely or partially provide the energy required to accelerate the motor vehicle.

The energy supply system comprises at least two conversion devices.

A conversion device designates herein in particular a device which is designed and configured to convert energy or electric current from one form into another form.

One of the at least two conversion devices can be, for example, an inverter. The inverter can be designed and configured to convert direct current, which can be supplied to the inverter from an electrochemical energy storage device, into alternating current.

At least one of the at least two conversion devices can be an electric machine, for example, an electric motor. The electric machine, for example, the electric motor, can be designed and configured to convert electrical energy, which can be supplied to the electric machine, for example, the electric motor, as alternating current, into a rotational movement, using which the motor vehicle can be accelerated.

The energy supply system comprises a connecting device, which connects the at least two conversion devices. The connecting device can preferably connect the at least two conversion devices in a current-conducting manner.

The energy supply system comprises at least one protective element described herein on at least one of the at least two conversion devices and/or on the connecting device to protect the surroundings of the energy supply system from electric, magnetic, or electromagnetic fields.

The energy supply system can preferably comprise a protective element described herein on at least one of the at least two conversion devices. The at least one protective element can be used to protect the surroundings of the energy supply system from electric, magnetic, or electromagnetic fields.

The energy supply system can preferably comprise at least one protective element described herein on the connecting device. The at least one protective element can be used to protect the surroundings of the energy supply system from electric, magnetic, or electromagnetic fields.

The energy supply system can preferably comprise at least one protective element described herein on at least one of the at least two conversion devices and on the connecting device. The at least one protective element can be used to protect the surroundings of the energy supply system from electric, magnetic, or electromagnetic fields.

The energy supply system can preferably comprise at least one first protective element described herein on at least one first one of the at least two conversion devices and can comprise at least one second protective element on at least one second one of the at least two conversion devices. Preferably, the second protective element can also be a protective element described herein. The at least two protective elements are used to protect the surroundings of the energy supply system from electric, magnetic, or electromagnetic fields.

It is preferred if at least one of the at least two conversion devices and/or the connecting device is entirely or partially accommodated in an interior or in a depression of the at least one protective element to protect the surroundings.

The connecting device can preferably comprise a cable or a cable strand.

The at least two conversion devices and the connecting device can represent sources of electric, magnetic, or electromagnetic fields. The at least one protective element which the energy supply system comprises can preferably be an emission protective element, which can protect devices that can be interfered with by electric, magnetic, or electromagnetic fields in the surroundings of the energy supply system.

It can be advantageous if a first one of the conversion devices is configured to convert an electrical current that can be supplied to the first conversion device into an electrical current that can be discharged from the first conversion device. The first of the conversion devices can preferably be a converter, for example, an inverter.

It can be advantageous if a second one of the conversion devices is configured to convert an electrical current that can be supplied to the second conversion device into a rotational movement.

Preferably, the shielding layer, for example, the first shielding layer, which has, for example, a relative permeability u, of at least 10, preferably of at least 50, particularly preferably of at least 250, very particularly preferably of at least 1000, for example, of at least 5000; and/or is ferromagnetic; and/or contains a mu-metal or is formed from a mu-metal, can be arranged closer to an inner surface of a depression of the protective element than another of the shielding layers, for example, the second shielding layer.

In particular, a source of electric, magnetic, or electromagnetic fields, which is entirely or partially accommodated in an interior or in a depression of the protective element, can then be shielded well. It has been found that a better shielding effect can result if a shielding layer having one of the indicated relative permeabilities, which is, for example, ferromagnetic and/or which contains the mu-metal, comes to rest particularly close to the source to be shielded.

It can be advantageous if a sealing material lies against or is arranged on the suspension zone in the energy supply system, wherein it can be advantageous if the sealing material extends around the installation recess.

It can be advantageous if a sealing material lies against or is arranged on the sealing layer in the energy supply system.

The object is achieved according to the invention via a communication system according to the independent claim in this regard.

The communication system can be, for example, a communication system for an entirely or partially electrically driven motor vehicle.

However, it is also conceivable that the communication system is a communication system for communication between different devices, for example, different motor vehicles.

Any system which enables a transmission of information between communication units of the communication system can be understood as a communication system. In particular, the communication system can be designed and configured to transmit information in the form of electric, magnetic, or electromagnetic signals.

Communication can be understood here in particular as any transmission of electric, magnetic, or electromagnetic signals, any control taking place via this, and any connection taking place via this of communication units of the communication system

The communication system comprises a first communication unit, which includes an interface for emitting an electric, magnetic, or electromagnetic signal.

In particular in motor vehicles, different communication units are installed, which enable a communication between various components of the vehicle or also between one or more components of the motor vehicle and occupants of the motor vehicle.

The first communication unit can be, for example, a control unit or a telecommunications unit.

The communication system comprises a second communication unit, which includes an interface for receiving the electric, magnetic, or electromagnetic signal of the first communication unit.

The second communication unit can be, for example, a control unit or a telecommunications unit.

The interfaces can be designed and configured to transmit the electric, magnetic, or electromagnetic signal via a transmission unit extending from the interface of the first communication unit to the interface of the second communication unit. The transmission unit can comprise, for example, a cable.

Alternatively, the interfaces can be designed and configured to transmit the electric, magnetic, or electromagnetic signal through a medium surrounding the interfaces. The medium can, for example, contain air or be air. The interface of the first communication unit can preferably include a transmitting unit or can be connected to a transmitting unit, using which the electric, magnetic, or electromagnetic signal can be emitted.

The interface of the second communication unit can include a receiving unit or can be connected to a receiving unit, which can receive the electric, magnetic, or electromagnetic signal of the first communication unit. The receiving unit can be designed and configured to be able to receive the electric, magnetic, or electromagnetic signal of the first communication unit.

The communication system comprises at least one protective element described herein for protecting at least one of the communication units from electric, magnetic, or electromagnetic fields, wherein it is preferred if the at least one of the communication units is entirely or partially accommodated in an interior or in a depression of the protective element to protect the at least one of the communication units from electric, magnetic, or electromagnetic fields.

It can be advantageous if a sealing material lies against or is arranged on the suspension zone in the communication system, wherein it can be advantageous if the sealing material extends around the installation recess.

It can be advantageous if a sealing material lies against or is arranged on the sealing layer in the communication system.

The object is achieved according to the invention by a motor vehicle according to the independent claim in this regard.

The motor vehicle can be, for example, an entirely or partially electrically driven motor vehicle.

The motor vehicle comprises a source of electric, magnetic, or electromagnetic fields.

The source can advantageously be a conversion device of an energy supply system of the motor vehicle, for example, an electric motor or an inverter, or a connecting device.

The connecting device can connect two conversion devices to one another. The connecting device can preferably connect two conversion devices to one another in a current-conducting manner.

The motor vehicle comprises a device that can be interfered with by electric, magnetic, or electromagnetic fields, wherein the device that can be interfered with by electric, magnetic, or electromagnetic fields can be or comprise, for example, a communication unit of the motor vehicle.

The motor vehicle comprises at least one protective element described herein, wherein the protective element is arranged entirely or partially between the source and the device that can be interfered with by the electric, magnetic, or electromagnetic fields.

It can be advantageous if a sealing material lies against or is arranged on the suspension zone in the motor vehicle, wherein it can be advantageous if the sealing material extends around the installation recess.

It can be advantageous if a sealing material lies against or is arranged on the sealing layer in the motor vehicle.

The object is achieved according to the invention by a method according to the independent claim in this regard.

The method is a method for producing a protective element described herein, an underbody protective element described herein, and/or a battery housing part described herein, wherein a surface area of a base body of the protective element, the underbody protective element, and/or the battery housing part is sealed by applying a plastic-containing sealing material.

It can be advantageous if the base body includes a shielding layer and/or a shielding layer extends through the base body and/or along a surface of the base body.

The shielding layer can in particular be the shielding layer described herein or one of the shielding layers described herein.

The shielding layer can be, for example, the shielding layer described herein in conjunction with the protective element or one of the shielding layers described herein in conjunction with the protective element.

It can be advantageous if the base body is formed in a molding tool from multiple starting materials flatly layered on one another partially or completely overlapping, wherein it can be advantageous if at least one of the starting materials is fiber-reinforced, wherein the plastic-containing sealing material is also introduced into the molding tool and/or the sealing of the surface area in the molding tool by the plastic-containing sealing material takes place directly during the production of the fiber-reinforced base body.

It can be advantageous if one of the starting materials layered on one another partially or completely overlapping is the shielding layer.

It can be advantageous if the base body contains a fiber connecting material and/or the fiber connecting material is also introduced into the molding tool. The fiber connecting material can preferably be the fiber connecting material described herein in conjunction with the protective element.

The fiber-reinforced starting material can preferably be a UD tape, wherein the UD tape includes the fiber connecting material.

For example, the plastic-containing sealing material can also be introduced into the molding tool and the sealing of the surface area in the molding tool by the plastic-containing sealing element can take place directly during the production of the fiber-reinforced base body.

It can be advantageous if the base body is a fiber-reinforced base body and the surface area is porous and/or a part of the reinforcement fibers of the base body extend up to the surface area of the base body.

The surface area can be a surface area existing at a reinforcement zone described herein. The reinforcement zone can occur in the molding tool during the formation of the base body.

It can be advantageous if the plastic-containing sealing material is a plastic film, in particular a plastic film described herein. Advantageously, a mean thickness of the plastic film can preferably be 10 μm to 500 μm, particularly preferably 25 μm to 400 μm, for example, 30 μm to 250 μm.

It can be advantageous if one of the sealing layers described herein is formed using the plastic film.

It can be advantageous if the plastic-containing sealing material contains reinforcement fibers. The plastic-containing sealing material containing reinforcement fibers can in particular be a UD tape.

It can be advantageous if one of the sealing layers containing reinforcement fibers described herein is formed using the UD tape.

It can be advantageous if a roughness of the surface area is reduced by the application of the sealing material.

The protective element described herein, underbody protective element described herein, and/or battery housing part described herein can be a protective element, underbody protective element, and/or battery housing part produced according to the method according to the invention.

Of course, features described in conjunction with one subject matter according to the invention can also form features of another subject matter according to the invention described herein. Subjects according to the invention are in this case in particular the protective element, the energy supply system, the communication system, the motor vehicle, and the method.

Further preferred features and/or advantages of the invention are the subject matter of the following description and the illustration in the drawings of exemplary embodiments.

### BRIEF DESCRIPTION OF THE DRAWINGS

FIG. 1: shows a schematic sectional view of a detail of a protective element;

FIG. 2: shows a schematic sectional view of a detail of a protective element;

FIG. 3: shows a schematic sectional view of a detail of a protective element, which is arranged on a ground of a motor vehicle;

FIG. 4: shows section A-A from FIG. 3;

FIG. 5: shows section B-B from FIG. 3;

FIG. 6: shows a schematic sectional view of a detail of a protective element, which is arranged on a ground of a motor vehicle;

FIG. 7: shows section C-C from FIG. 6;

FIG. 8: shows section D-D from FIG. 6;

FIG. 9: shows a schematic sectional view of a detail of a protective element, which is arranged on a ground of a motor vehicle;

FIG. 10: shows section E-E from FIG. 9;

FIG. 11: shows section F-F from FIG. 9;

FIGS. 12-14: show schematic views of experimental setup for checking the shielding-attenuation effect of various protective elements;

FIG. 15: shows shielding attenuations for the experimental setup from FIG. 12;

FIG. 16: shows shielding attenuations for the experimental setup from FIG. 13;

FIG. 17: shows a schematic perspective view of a protective element;

FIG. 18: shows a schematic perspective view of a part of an energy supply system;

FIG. 19: shows a section through FIG. 18;

FIG. 20: shows a schematic view of a communication system;

FIG. 21: shows a schematic perspective view of a protective element;

FIG. 22: shows a detail of a section through the protective element shown in FIG. 21;

FIG. 23: shows a detail of a section through a further protective element;

FIG. 24: shows a further view of a protective element;

FIG. 25: shows a rough simplified view of a section through a protective element;

FIG. 26: shows a detail of a section through a further protective element;

FIG. 27: shows an alternative arrangement of contacting element and seal element;

FIG. 28: shows a contacting element on a carrier;

FIG. 29: shows a detail of a protective element in a perspective view;

FIG. 30: shows a further contacting element on a carrier;

FIG. 31: shows a detail of a section through a further protective element;

FIG. 32: shows a detail of a section through a further protective element;

FIG. 33: shows a detail of a section through a further protective element;

FIG. 34: shows a detail of a section through a further protective element;

FIG. 35: shows a detail of a section through a further protective element;

FIG. 36: shows a detail of a section through a further protective element;

FIG. 37: shows a perspective view of a section through a protective element having reinforcement zone; and

FIG. 38: shows an enlarged view of a detail from FIG. 37.

### DETAILED DESCRIPTION OF THE DRAWINGS

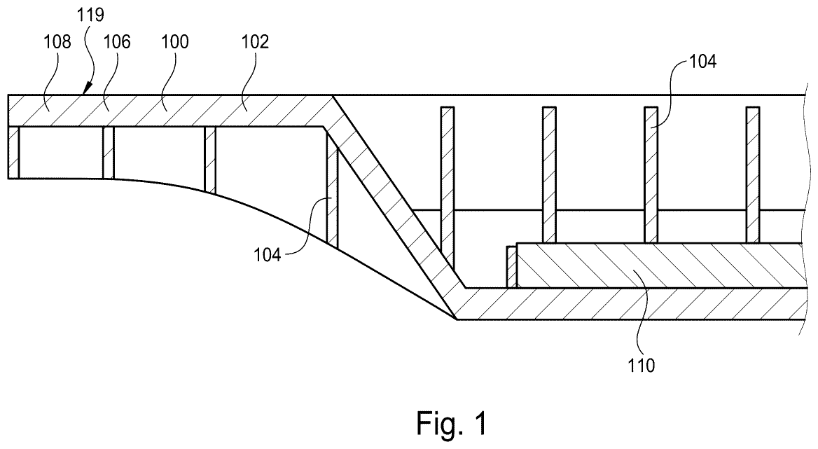

FIG. 1 shows a protective element 102 embodied as an aluminum component 100. The protective element 102 comprises reinforcement ribs 104, which also consist of aluminum. The protective element 102 shown can be installed as a battery housing part 106. It can function in this case in particular as an underbody protective element 108.

The protective element 102 comprises an insulation layer 110, which can consist, for example, of a foam material.

The protective element 102 comprises a protective element surface 119 for attaching the protective element to a device that can be interfered with by electric, magnetic, or electromagnetic fields or to a source of electric, magnetic, or electromagnetic fields.

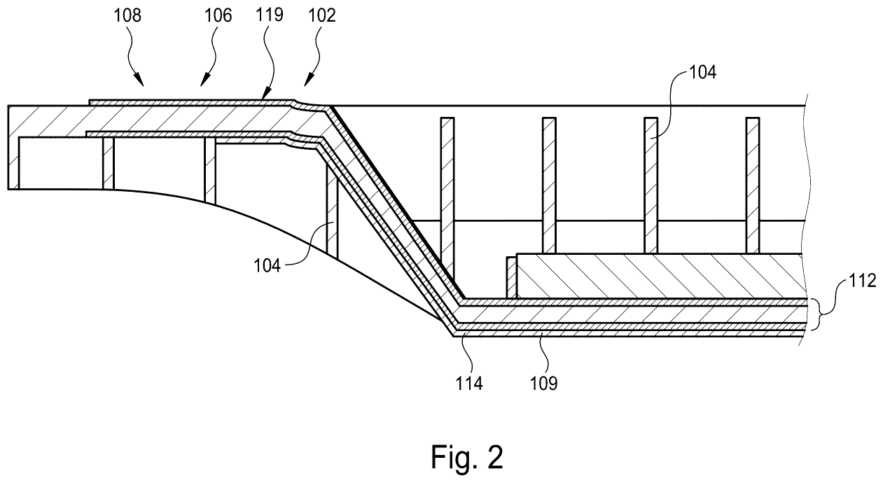

The protective element shown in FIG. 2 differs from the protective element shown in FIG. 1 in that it is not embodied as an aluminum component 100, but rather from a separate shielding component 109 and a further housing component 112, wherein the shielding component 109 and the housing component 112 are manufactured separately and then joined. The shielding component 109 can be manufactured from aluminum, for example, and can form a shielding layer 114, which is capable of substantially shielding electromagnetic radiation.

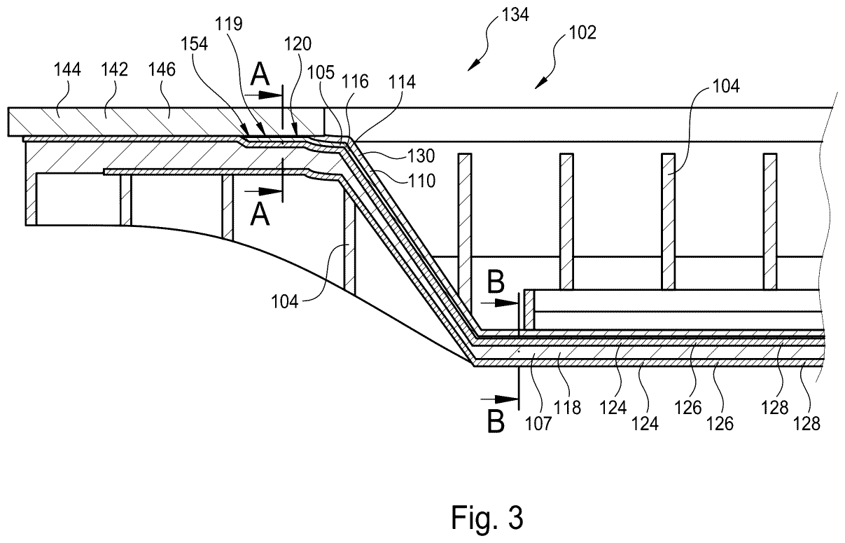

FIG. 3 shows a protective element 102. The protective element 102 comprises a shielding layer 114. The shielding layer 114 is a foil 105, for example, an aluminum foil 116. The protective element 102 comprises a plastic layer 118.

The protective element 102 shown in FIG. 3 comprises a contacting zone 120. The contacting zone 120 is an outer surface contacting zone 154. The protective element surface 119 comprises the outer surface contacting zone 154.

The protective element 102 shown in FIG. 3 comprises reinforcement layers 124. These are reinforcement layers 124 reinforced using fibers 126. The reinforcement layers 124 reinforced using fibers 126 are organic sheets 128.

The protective element shown in FIG. 3 comprises a protective layer 130. The protective layer 130 is an insulation layer 110. The insulation layer 110 can be electrically insulating and can be an electrically insulating protective layer 130. Alternatively or additionally, the insulation layer can be a high-temperature thermal insulation layer.

The ground 142 also shown in FIG. 3 forms a part of a device on which the protective element 102 can be arranged. In a motor vehicle and also in motorcycles and bicycles, the ground potential is the body or the frame. The term “ground” refers to this ground potential. In FIG. 3, the ground 142 is a frame 146 associated with a carrier structure 144. An electrical contact between the shielding layer 114 and the frame 146 comprised by the device exists via the contacting zone 120.

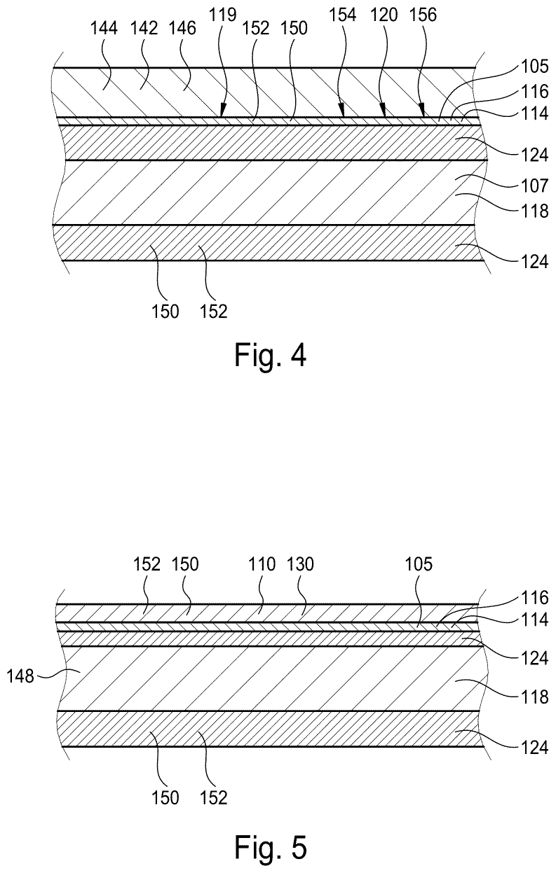

FIG. 4 shows section A-A from FIG. 3. An outer surface 156 of the shielding layer 114 forms the outer surface contacting zone 154.

In the area of the protective element 102 which section A-A shows, the shielding layer 114 is on the very outside in the layer structure. It forms a cover layer 152. The outer surface contacting zone 154 is in direct electrical contact with the ground 142. An electrical contact can therefore be established between the shielding layer 114 and the device which comprises the ground 142 by means of the outer surface contacting zone 154.

FIG. 5 shows section B-B from FIG. 3. The plastic layer 118 is a plastic core 148, which is arranged between reinforcement layers 124. One of the reinforcement layers 124 forms a cover ply 150. In the layer composite, the cover ply 150 forms a cover layer 152. The shielding layer 114 is arranged between the outer reinforcement layer 124 and the insulation layer 110, which forms a protective layer 130. The insulation layer 110 represents a further cover ply 150, which forms a further cover layer 152 in the layer composite.

A final layer in the layer structure of the layer composite is referred to herein as a cover layer 152.

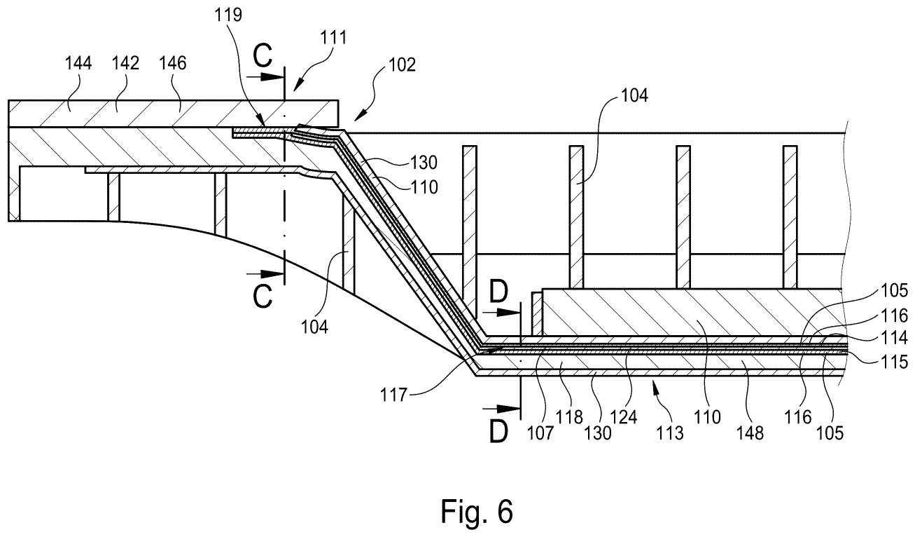

The protective element 102 shown in FIG. 6 comprises a first shielding layer 114 for protection from electric, magnetic, or electromagnetic fields and a second shielding layer 115 for protection from electric, magnetic, or electromagnetic fields.

The protective element 102 shown in FIG. 6 comprises a shielding zone 113, in which the first and the second shielding layer 114 and 115 are spaced apart from one another. An intermediate layer 107 is arranged between the first shielding layer 114 and the second shielding layer 115. In the example shown here, the intermediate layer 107 is a reinforcement layer 124.

The intermediate layer 107 is arranged in the shielding zone 113 between the first shielding layer 114 and the second shielding layer 115.

A layer composite zone 117 is present, in which the first and the second shielding layer are connected by means of the intermediate layer 107. The layer composite zone 117, in which the first and the second shielding layer are connected by means of the intermediate layer 107, is present in the shielding zone 113.

The two shielding layers 114 and 115 are electrically conductive.

In the layer composite zone 117, in addition an insulation layer 110 is bound to a surface of the first shielding layer 114 and a plastic layer 118 is bound to a surface of the second shielding layer 115. The plastic layer 118 is present in the layer structure between a protective layer 130 and the second shielding layer 115. The layer structure is clear in particular from FIG. 8, which shows the section through the protective element 106 on FIG. 6 along line D-D. The insulation layer 110 on the first shielding layer 114 represents a cover ply 150, which forms a cover layer 152 in the layer composite. The protective layer 130 on the plastic layer 118 represents a further cover ply 150, which forms a further cover layer 152 in the layer composite.

It is clear from FIGS. 6 and 8 that the shielding layers 114 and 115 are each foils 105. These can each be aluminum foils 116, for example.

The protective element 102 shown in FIG. 6 comprises a contact zone 111, in which the first shielding layer 114 and the second shielding layer 115 are in electrical contact.

The protective element 102 also comprises a protective element surface 119. The protective element surface can be used to attach the protective element 102 to a device that can be interfered with by electric, magnetic, or electromagnetic fields or to a source of electric, magnetic, or electromagnetic fields.

The ground 142 likewise shown in FIG. 6 forms a part of such a device. The protective element 102 can be arranged on this device. The ground 142 in the example shown here is a frame associated with a carrier structure 144, for example, of a motor vehicle.

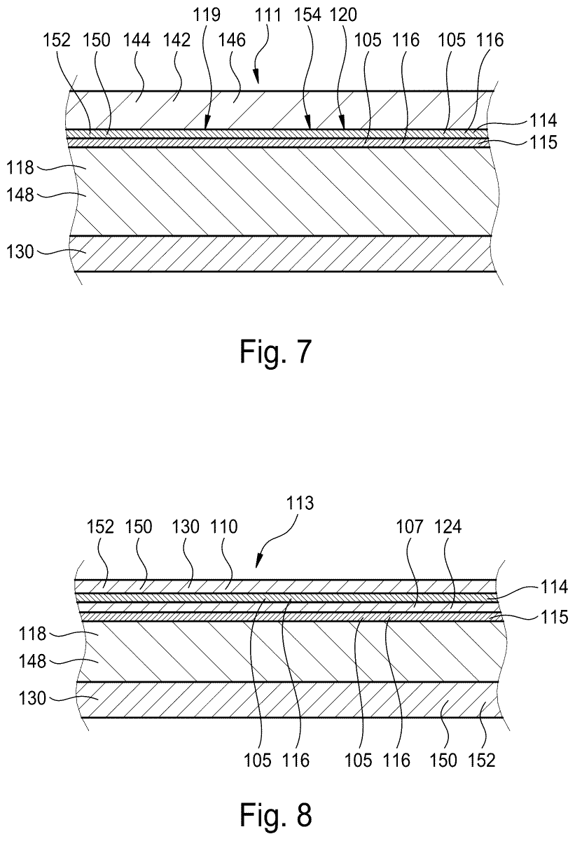

FIG. 7 shows a section through the protective element from FIG. 6 along line C-C.

The section shown in FIG. 7 also extends through the ground 142.

It is clear from FIG. 7 in particular that the first shielding layer 114 and the second shielding layer 115 are in electrical contact in the contact zone 111, through which the section shown in FIG. 7 is made. The reinforcement layer 124 functioning as the intermediate layer 107 thus does not extend into the contact zone 111. Surfaces of the shielding layer 114 and the shielding layer 115 facing toward one another are in electrical contact in the contact zone 111.

FIG. 7 also shows that the protective element 102 shown in FIG. 6 comprises a contacting zone 120. The contacting zone 120 is an outer surface contacting zone 154. The protective element surface 119 comprises the outer surface contacting zone 154.

In the area of the protective element 102 which section C-C shows, the first shielding layer 114 is on the very outside in the layer structure. It forms a cover layer 152.

The outer surface contacting zone 154 is in direct electrical contact with the ground 142. An electrical contact can therefore be established between the first shielding layer 114 and the device which comprises the ground 142 by means of the outer surface contacting zone 154.

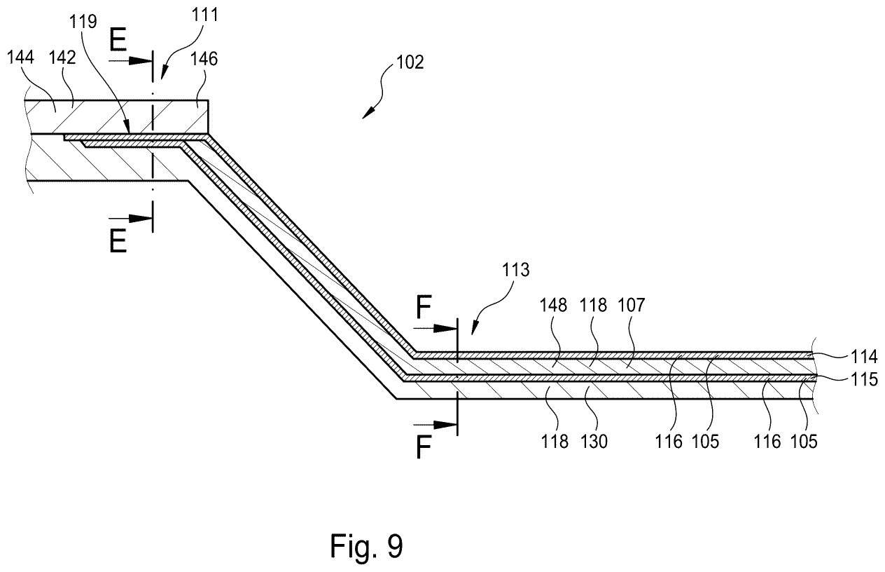

FIG. 9 shows a schematic view of a further protective element 102. The protective element 102 comprises a first shielding layer 114 and a second shielding layer 115. In the example shown, the two shielding layers are foils 105, wherein the foils can be, for example, aluminum foils 116. The first shielding layer 114 and the second shielding layer 115 are spaced apart from one another in a shielding zone 113 comprised by the protective element 102.

Between the first shielding layer 114 and the second shielding layer 115, the protective element 102 comprises an intermediate layer 107. The intermediate layer 107 is a plastic layer 118 in the example shown here. The plastic layer 118 forms a plastic core 148 of the protective element 102.

The protective element shown in FIG. 9 additionally comprises a protective layer 130. The protective layer 130 is a plastic layer 118. The protective layer 130 is arranged on a surface of the second shielding layer 115 facing away from the intermediate layer 107. The first shielding layer 114, the intermediate layer 107, the second shielding layer 115, and the protective layer 130 form a layer composite.

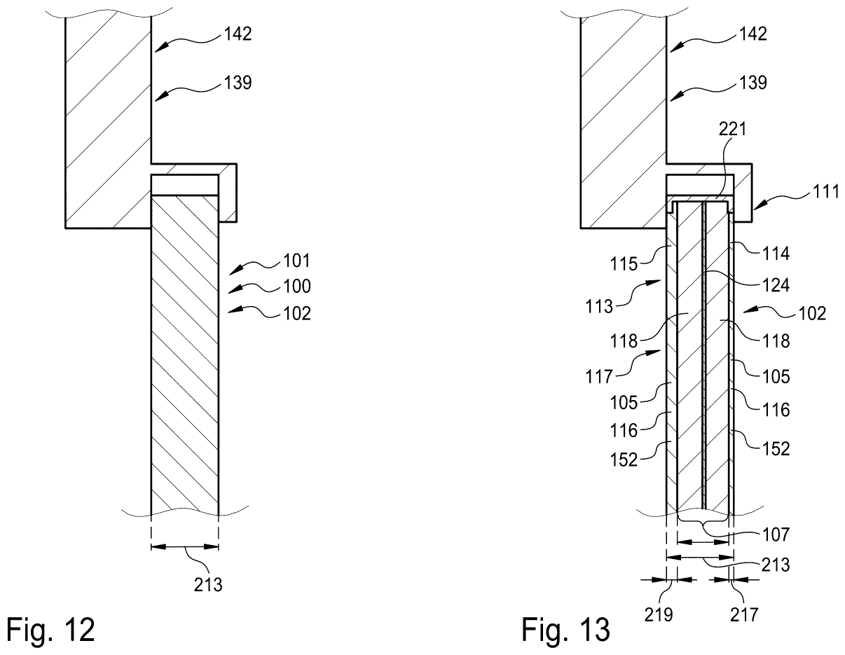

The first shielding layer 114 and the protective layer 130 represent cover layers 152 of the protective element 102. This is clear in particular from FIG. 11, which shows a section through the protective element 102 shown in FIG. 9 along line F-F.

The protective element shown in FIG. 9 comprises a contact zone 111, in which the first shielding layer 114 and the second shielding layer 115 are in electrical contact.

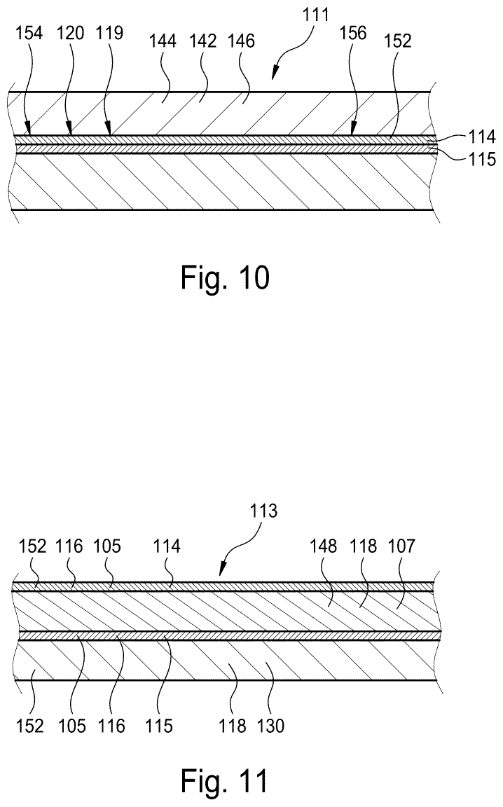

FIG. 10 shows a section through the protective element from FIG. 9 along line E-E. It is clear in particular from FIG. 10 that surfaces of the two shielding layers 114 and 115 facing toward one another are in direct electrical contact. The intermediate layer 107 does not extend into the contact zone 111.

The protective element 102 shown in FIG. 9 comprises a protective element surface 119. The protective element 102 can be attached on the protective element surface 119 to a device that can be interfered with by electric, magnetic, or electromagnetic fields or to a source of electric, magnetic, or electromagnetic fields. FIG. 9 shows a possibility for attaching the protective element 102 to a ground 142 via the protective element surface 119. The ground 142 can be part of a device to which the protective element 102 is attached. The ground can be a frame 146 associated with a carrier structure 144.

The protective element 102 shown in FIG. 9 also comprises a contacting zone 120. The contacting zone 120 is an outer surface contacting zone 154. The protective element surface 119 comprises the outer surface contacting zone 154. An outer surface 156 of the first shielding layer 114 forms the outer surface contacting zone 154.

In the contact zone 111 shown in FIG. 10, the first shielding layer 114 is on the very outside in the layer structure. It forms a cover layer 152. The outer surface contacting zone 154 is in direct electrical contact with the ground 142. An electrical contact can therefore be established between the first shielding layer and the device which comprises the ground 142 by means of the outer surface contacting zone.

FIGS. 12 to 14 each schematically show an experimental setup for measuring the shielding attenuation. The same holding element 139, which also represents a ground 142, is shown in each case in FIGS. 12 to 14. A protective element 102 is arranged in the holding element 139 in each case. The protective elements 102 shown in each of FIGS. 12 to 14 are different. In the structure in FIG. 12, an aluminum component 100 in the form of an aluminum plate 101 is used as the protective element 102. The protective element thickness 213 corresponds to the thickness of the aluminum plate 101.

In the experimental set up shown in FIG. 13, the protective element 102 is a protective element which comprises a first shielding layer 114 and a second shielding layer 115. Both shielding layers are foils 105. These are aluminum foils 116.

The protective element 102 shown in FIG. 13 comprises a shielding zone 113, in which the first shielding layer 114 and the second shielding layer 115 are spaced apart from one another.

FIG. 13 additionally shows that a multi-ply intermediate layer 107 is arranged between the first shielding layer 114 and the second shielding layer 115. The multi-ply intermediate layer 107 comprises two plastic layers 118 and a reinforcement layer 124.

The two shielding layers 114 and 115 each form a cover layer 152. The cover layers 152 located on the outside in the layer structure are each attached via one of the plastic layers 118 to the reinforcement layer 124.

The protective element 102 shown in FIG. 13 comprises a contact zone 111. An electrical contact is established via a copper band 221 in the contact zone 111 between the first shielding layer 114 and the second shielding layer 115.

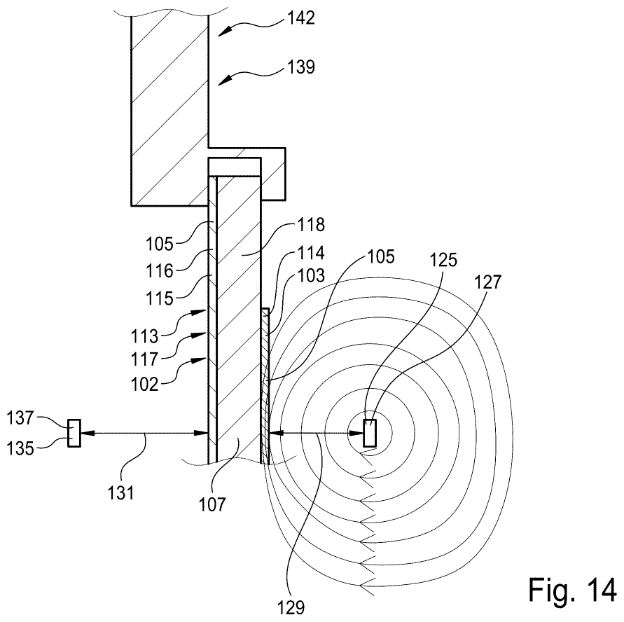

In FIG. 14, the protective element 102 comprises a first shielding layer 114 and a second shielding layer 115. The first shielding layer 114 is a shielding layer formed from a mu-metal 103. It is a foil 105 formed from the mu-metal 103. In a shielding zone 113 comprised by the protective element 102, the first shielding layer 114 and the second shielding layer 115 are spaced apart from one another. An intermediate layer 107 is arranged between the first shielding layer 114 and the second shielding layer 115. The intermediate layer is arranged in the shielding zone 113 between the first shielding layer 114 and the second shielding layer 115. The intermediate layer 107 is a plastic layer 118.

The protective element shown in FIG. 14 includes a layer composite zone 117, in which the first shielding layer 114 and the second shielding layer 115 are connected by means of the intermediate layer 107. The layer composite zone 117, in which the first shielding layer and the second shielding layer are connected by means of the intermediate layer 107, is present in the shielding zone 113.

The protective element 102 shown in FIG. 14 also differs from the protective element 102 shown in FIG. 13 in that it does not comprise a contact zone 111. In the protective element shown in FIG. 14, the first shielding layer 114 and the second shielding layer 115 are not in electrical contact with one another. Electrical contact is also not established between the first shielding layer 114 and the second shielding layer 115. Establishing such an electrical contact between the first shielding layer 114 and the second shielding layer 115 is not provided in the protective element shown in FIG. 14.

In addition, a source 127 of electromagnetic radiation is shown in FIG. 14. The source 127 can be, for example, a transmitter 125. The transmitter is arranged at a distance 129 to the protective element 102. The distance 129 can be varied arbitrarily.

In addition, a receiver 137 is shown in FIG. 14, which can include a sensor, for example, using which a power density can be measured at a given distance 131 to the protective element 102.

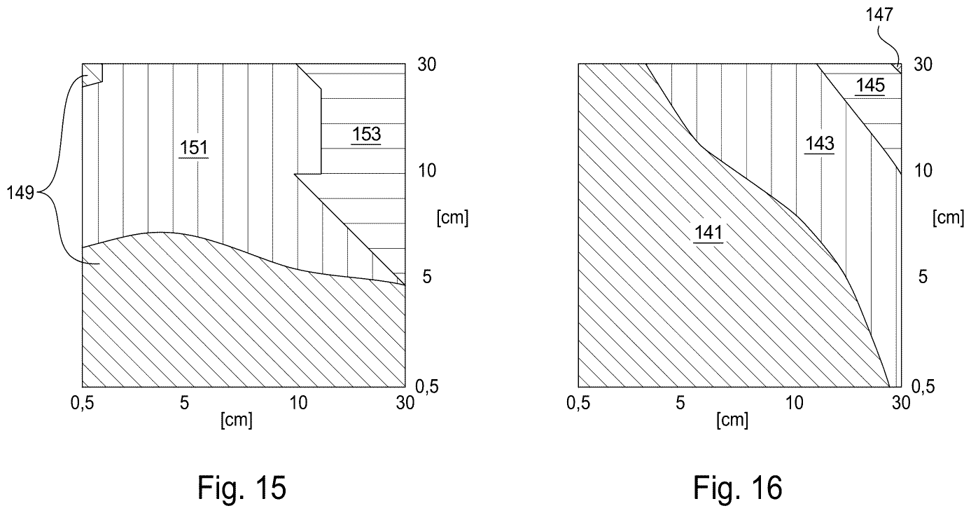

FIG. 15 shows the shielding attenuation in the experimental setup shown in FIG. 12 as a function of the distance 131 to the receiver 137 (horizontal axis) and as a function of the distance 129 of the transmitter 125 (vertical axis).

FIG. 16 shows the shielding attenuation in the experimental setup shown in FIG. 13 as a function of the distance 131 to the receiver 137 (horizontal axis) and as a function of the distance 129 of the transmitter 125 (vertical axis).

The shielding attenuations shown in FIGS. 15 and 16 are shielding attenuations of electromagnetic radiation at a frequency of 0.15 MHz.

A shielding attenuation of 70 to 72 dB was achieved in the area provided with reference sign 141.

A shielding attenuation of 68 to 70 dB was achieved in the area provided with reference sign 143.

A shielding attenuation of 66 to 68 dB was achieved in the area provided with reference sign 145.

A shielding attenuation of 64 to 66 dB was achieved in the area provided with reference sign 147.

A shielding attenuation of 59.5 to 60.5 dB was achieved in the area provided with reference sign 149.

A shielding attenuation of 58.5 to 59.5 dB was achieved in the area provided with reference sign 151.

A shielding attenuation of 57.5 to 58.5 dB was achieved in the area provided with reference sign 153.

The thickness 217 of the first shielding layer 114 was only 0.15 mm in the experimental setup of FIG. 13. The thickness 219 of the second shielding layer 115 was only 0.2 mm in the same experimental setup. In contrast, an aluminum plate 101 having a thickness of 10 mm was used in the experimental setup of FIG. 12. In the experimental setup of FIG. 13, the thickness of the intermediate layer 107 was selected so that a thickness of the protective element 102 of a total of 10 mm also resulted in this experimental setup. In both experimental setups, the protective element thickness was thus 10 mm. However, in total only approximately 3.5% of the aluminum which was contained in the aluminum plate 101 of the experimental setup shown in FIG. 12 was used in the experimental setup of FIG. 13.

Surprisingly, stronger shielding attenuations were measured throughout using the protective element 102 of the experimental setup from FIG. 13 in spite of the significantly lower content of electrically conductive material at all tested distances 129 and 131 than using the aluminum plate 101 of the experimental setup from FIG. 12.

It is presumed that the reflection can be increased using protective elements 102 according to the invention. An increased reflection factor presumably contributes to the increased shielding-attenuation effect.

It is presumed that similar increases of the shielding properties can be achieved in particular at close range (wavelength in the meter range) using a protective element according to FIG. 14. Magnetic field components can be redirected using a ferromagnetic shielding layer. It has been shown in this case that this is also possible without the production of an electrical contact of the ferromagnetic shielding layer with a further shielding layer.

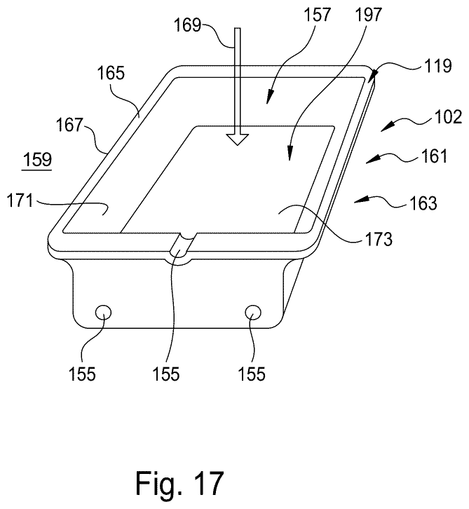

FIG. 17 shows a protective element 102. The protective element 102 is an inverter housing element 161. However, it can also be used as a housing for another source of electric, magnetic, or electromagnetic fields and can therefore be used in a different way as a housing element 163.

The protective element shown in FIG. 17 comprises an interior 157. The interior 157 is enclosed by a side wall 171 and extends into a depression 197 up to a wall 173, from which the side wall 171 extends around the interior 157. The side wall 171 extends from the wall 173 up to a protective element surface 119. The protective element surface 119 is formed on a flange 165, which extends up to a protective element edge 167. The side wall 171 separates the interior 157 from an exterior 159 enclosing the protective element 102.

The protective element 102 shown in FIG. 17 comprises multiple feedthrough zones 155. Connecting devices 211, in particular electrical conductors, such as cables 191 or cable strands 193, can extend through the feedthrough zones 155 from the exterior 159 to an inverter which can be accommodated in the interior 157.

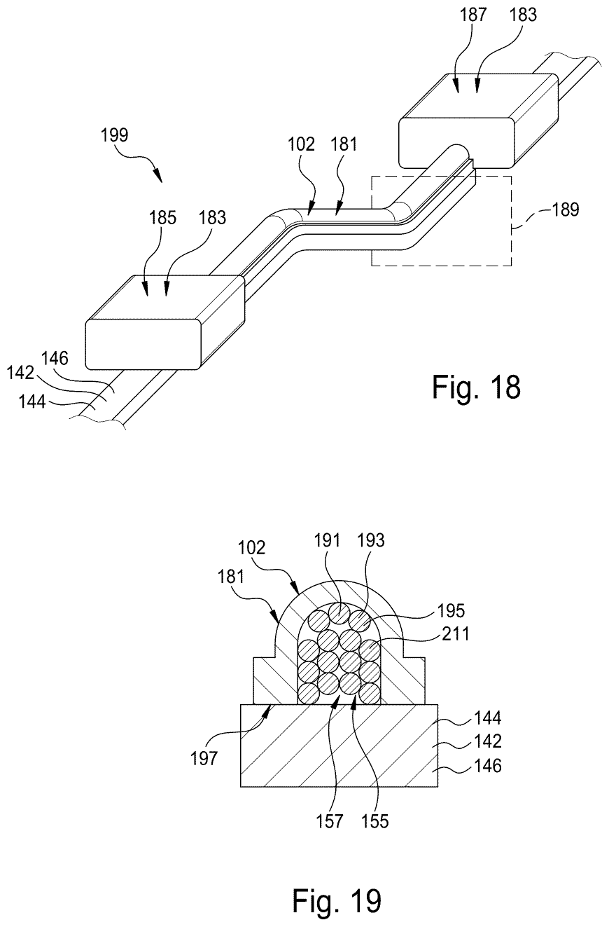

FIG. 18 shows a detail of a schematically shown energy supply system 199. The energy supply system 199 is an energy supply system 199 for an entirely or partially electrically driven motor vehicle.

The energy supply system 199 comprises multiple conversion devices 183. The conversion devices 183 are only schematically shown.

One of the conversion devices 183 is an electric motor 187 in the detail shown of an energy supply system 199.

Another conversion device 183 is an inverter 185.

The electric motor 187 forms a conversion device 183, since it is capable of converting electrical energy into a rotational movement.

The inverter 185 is a conversion device 183, since it is capable of converting direct current, which can be supplied to the inverter 185, for example, by an electrochemical energy storage device, into alternating current. The alternating current can be supplied to the electric motor 187.

The energy supply system 199 comprises a connecting device 211. This can be seen in particular in the section shown in FIG. 19. The associated sectional plane 189 is indicated by dashed lines in FIG. 18.

The connecting device 211 connects the two conversion devices 183.

The connecting device 211 comprises a cable 191. The cable can be associated with a cable strand 193 shown in FIG. 19.

The connecting device 211, the cable 191, and the cable strand 193 each form a source of electric, magnetic, or electromagnetic fields.

The energy supply system 199 comprises a protective element 102. The protective element 102 is arranged on the connecting device 211 to protect the surroundings of the energy supply system 199 from electric, magnetic, or electromagnetic fields.

To protect the surroundings, the connecting device 211 is accommodated in an interior 157 of the protective element 102. The interior 157 is formed by a depression 197 of the protective element 102. The connecting device 211 is accommodated in the depression 197 of the protective element 102.

The interior 157 represents a feedthrough zone 155, which extends from one end of the protective element 102, which faces toward the inverter 185, to another end of the protective element 102, which faces toward the electric motor 187.

The protective element 102 is shown greatly simplified in each of FIGS. 17, 18, and 19. It is a protective element according to the invention in each case. However, the layer structure is not shown.

The protective elements 102 of the housing element 163 or the energy supply system 199 can be constructed, for example, as shown in one of FIGS. 6 to 14.

The protective element 102 shown in FIGS. 18 and 19 only has a specific shape which is used for shielding cable-shaped sources 195. The protective element 102 can be, for example, a cable shielding element 181.

It comprises a protective element surface 119. The protective element surface 119 is used to attach the protective element to a carrier structure 144 of a frame 146 used as a ground 142. Since the source 195 extends along a surface of the carrier structure 144, the protective element surface 119 is used at the same time to attach the protective element 102 to the source 195 of electric, magnetic, or electromagnetic fields.

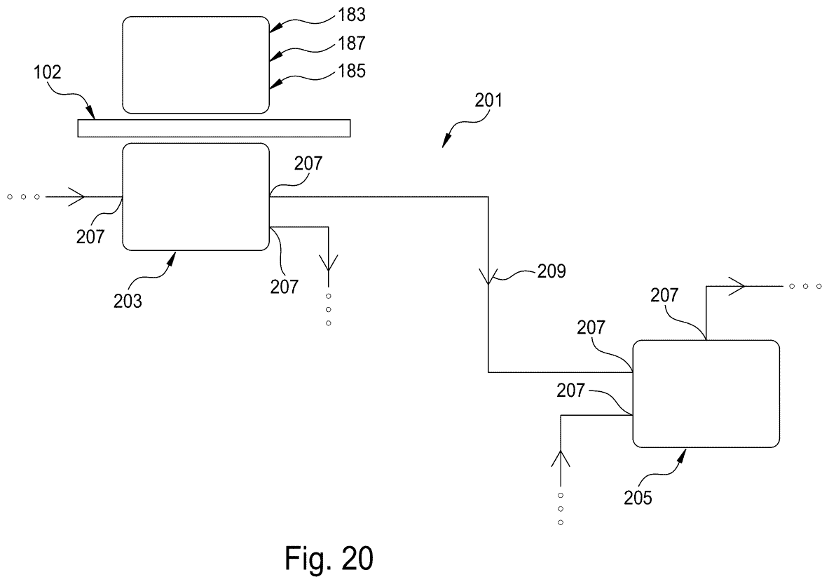

FIG. 20 schematically shows a communication system. The communication system 201 is a communication system 201 for an entirely or partially electrically driven motor vehicle.

The communication system 201 comprises a first communication unit 203, which includes an interface 207 for emitting an electric, magnetic, or electromagnetic signal 209. The first communication unit 203 additionally includes further interfaces 207.

The communication system 201 comprises a second communication unit 205, which includes an interface 207 for receiving the electric, magnetic, or electromagnetic signal 209 of the first communication unit.

In the example shown, a cable connection used to transmit the signal 209 from an interface 207 of the first communication unit 203 to an interface 207 of the second communication unit 205 is indicated.

The signal 209 could likewise be transmitted wirelessly, however. Thus, for example, the first communication unit 203 could include an interface 207 for emitting the signal 209, which transmits the signal 209 on a surrounding medium, for example, air. The second communication unit 205 could include an interface to receive the signal 209 from the medium, for example, air. Thus, for example, the interface 207 of the first communication unit 203 could comprise a transmitter and the interface 207 of the second communication unit 205 could comprise a receiver.

Like the first communication unit 203, the second communication unit 205 can also include further interfaces 207, which are indicated in FIG. 20.

The first communication unit 203 can be, for example, a control unit of a motor vehicle.

The second communication unit 205 can be, for example, a control unit of a motor vehicle.

The two communication units 203 and 205 can be, for example, control units of a motor vehicle.

In particular if the signal 209 is a signal 209 transmitted via the medium, for example, air, the first communication unit 203 can be a communication unit of one motor vehicle and the second communication unit 205 can be a communication unit of a further motor vehicle.

The communication system 201 shown in FIG. 20 comprises a protective element 102, which is only schematically shown in FIG. 20. The protective element 102 is used to protect the first communication unit 203 from electric, magnetic, or electromagnetic fields. The layer structure of the protective element 102 is not shown.

FIG. 20 shows, in addition to the communication system 201, a conversion device 183. The conversion device 183 can be, for example, an electric motor 187 or an inverter 185. The protective element 102 is used to protect a communication unit 203 from electric, magnetic, or electromagnetic fields, which can be generated by the conversion device 183.

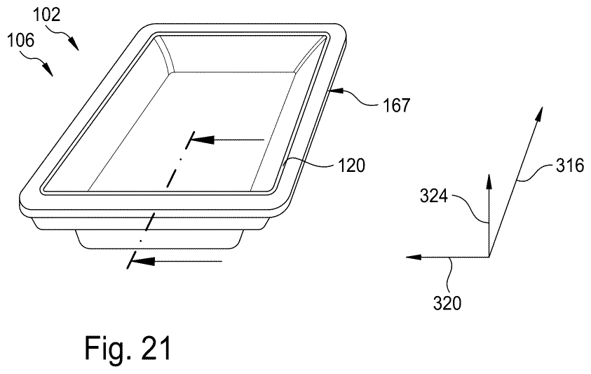

FIG. 21 shows a protective element 102 which is shown in roughly simplified form and which can be, for example, a battery housing part 106 or a housing tray for an electrochemical energy storage device of a motor vehicle, for example, for a high-voltage battery device.

A contacting zone 120 of the protective element 102 is also indicated in FIG. 21.

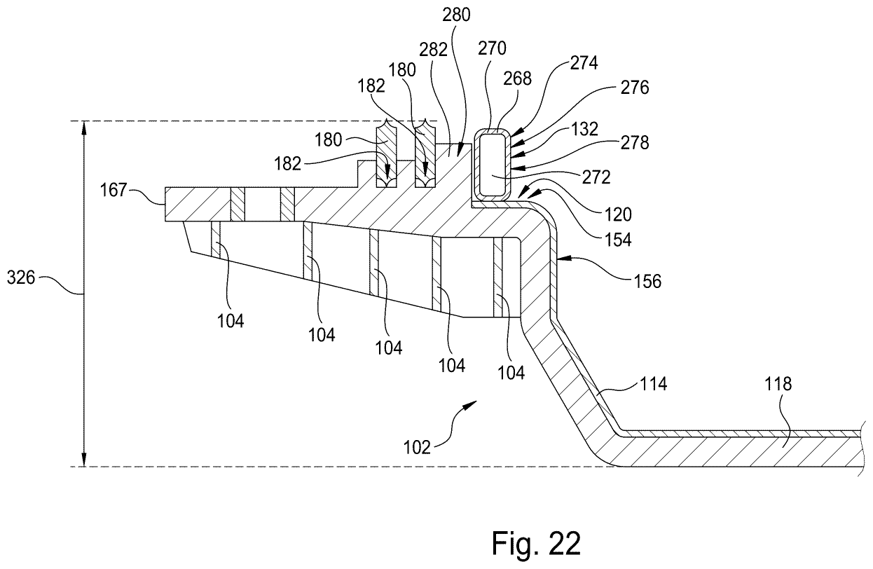

FIG. 22 shows a section through the protective element 102 from FIG. 21 along the dot-dash line, wherein further details are shown in the section.

The contacting element 132 additionally shown in FIG. 22 is deformable and elastic. The contacting element 132 includes fibers 268, which are contained in a fibrous material 270.

The contacting zone 120 is an outer surface contacting zone 154, wherein the outer surface contacting zone 154 is formed on an outer surface 156 of the shielding layer 114.

The fibrous material 270 of the contacting element 132 extends around a compression zone 272. During an installation of the protective element 102 on a motor vehicle, the contacting element 132 can be deformed, wherein the contacting element 132 and its compression zone 272 are compressed, for example, rammed, in particular in the installation direction.

The contacting element 132 shown is a hollow contacting element 274, through which the compression zone 272 extends. The contacting element 132 can be, for example, a fiber material tube 278, for example, a fabric tube 276.

The protective element 102 includes a positioning and/or alignment element 280, which in the example shown here is a positioning and/or alignment projection 282. The positioning and/or alignment element 280 is arranged at the contacting zone 120.

The fiber material tube 278, for example, the fabric tube 276, is arranged on the positioning and/or alignment element 280, for example, on the positioning and/or alignment projection 282 and on the contacting zone 120.

The protective element includes two seal elements 180, which are each partially accommodated in a seal element receptacle 182. The seal elements 180 can independently of one another contain, for example, an elastic sealing material or can be produced therefrom, for example, a natural or synthetic rubber, e.g., an ethylene-propylene-diene rubber (EPDM), a silicone rubber (VMQ), and/or a fluorine rubber (FPM), a polyurethane (PU), and/or an ethylene tetrafluoroethylene (ETFE).

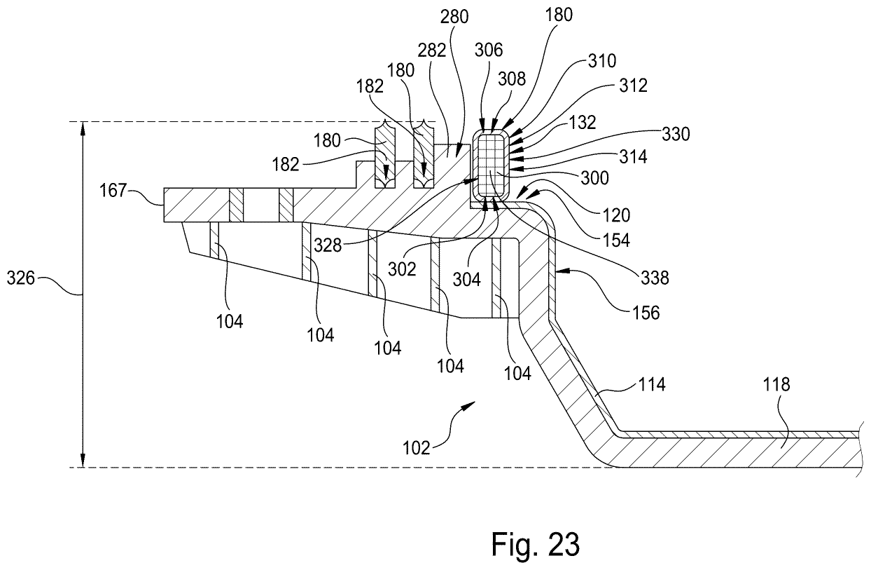

FIG. 23 shows a section through another protective element 102, which differs with regard to the contacting element 132 from the protective element 102 shown in FIGS. 21 and 22. The contacting element 132 is arranged on a deformable and/or elastic carrier 300. The contacting element 132 extends from an inner side 302 of the carrier 300 up to an outer side 306 of the carrier 300. The inner side 302 of the carrier 300 is at the same time a protective element side 304 of the carrier 300. It faces toward the contacting zone 120. The outer side 306 of the carrier is at the same time a device side 308 of the carrier 300 which faces away from the contacting zone 120.

The carrier 300 contains an elastic sealing material 338, from which the carrier 300 can preferably be produced. The elastic sealing material 338 can be, for example, an ethylene-propylene-diene rubber (EPDM).

An electrical contact bridged by the contacting element 132 can be established in each case between the contacting zone 120 and a device to be contacted, wherein a surface of the contacting element 132 is in electrically conductive contact with the contacting zone 120, and a further surface of the contacting element 132, on the outer side 306 of the carrier, can be brought into electrically conductive contact with the device.

The contacting elements 132 shown in FIGS. 22 and 23 are each electrically conductive.

The contacting element 132 shown in FIG. 23 contains an electrically conductive material 310. The electrically conductive material 310 can be or contain a metallic material 312, in particular aluminum 314.

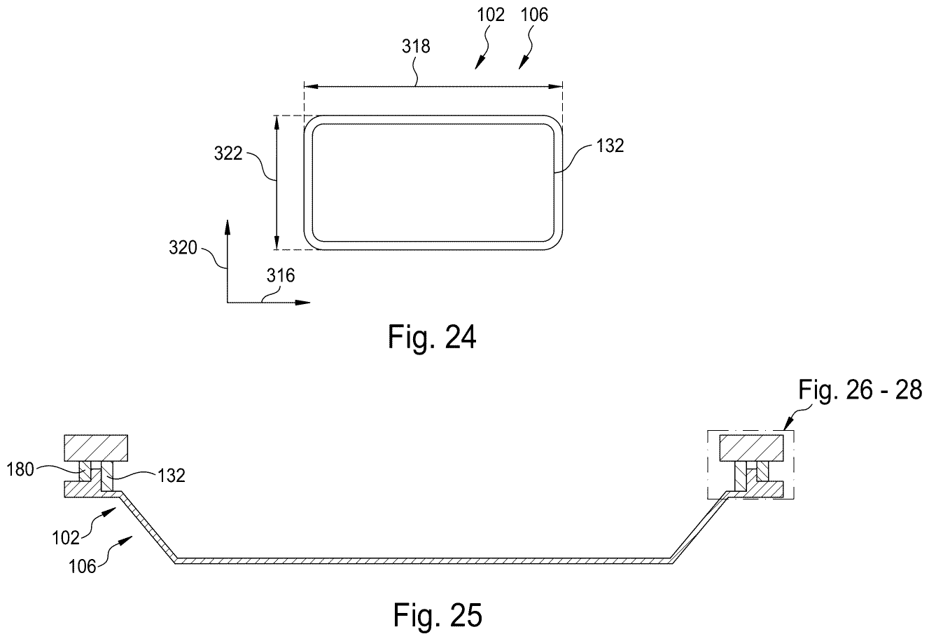

FIG. 24 shows the protective element 102, which is also shown in FIGS. 21 and 22, in a top view.

The protective element 102 shown in FIGS. 21, 22, and 24 has an extension 318 in a first direction 316 which is greater than an extension 322 of the protective element 102 in a second direction 320, which is aligned orthogonally to the first direction 316.

The extension 322 of the protective element 102 in the second direction 320 is greater than an extension 326 of the protective element 102 in a third direction 324, which is aligned orthogonally to the first direction 316 and to the second direction 320.

The first extension 318 can be a length of the protective element 102. The second extension 322 can be a width of the protective element 102. The third extension 326 can be a depth of the protective element 102.

For example, the length can be approximately 2 m to 3 m, the width approximately 1 m to 2 m, and the depth approximately 5 cm to 50 cm.

It can be seen clearly in FIG. 23 that the contacting element 132 extends around the carrier. It extends on both sides, on an edge side 328 of the carrier 300, which faces toward a protective element edge 167, and on an edge-averted side 330 of the carrier 300, which faces away from a protective element edge 167, in each case from the inner side 302 and/or protective element side 304 to the outer side 306 and/or device side 308.

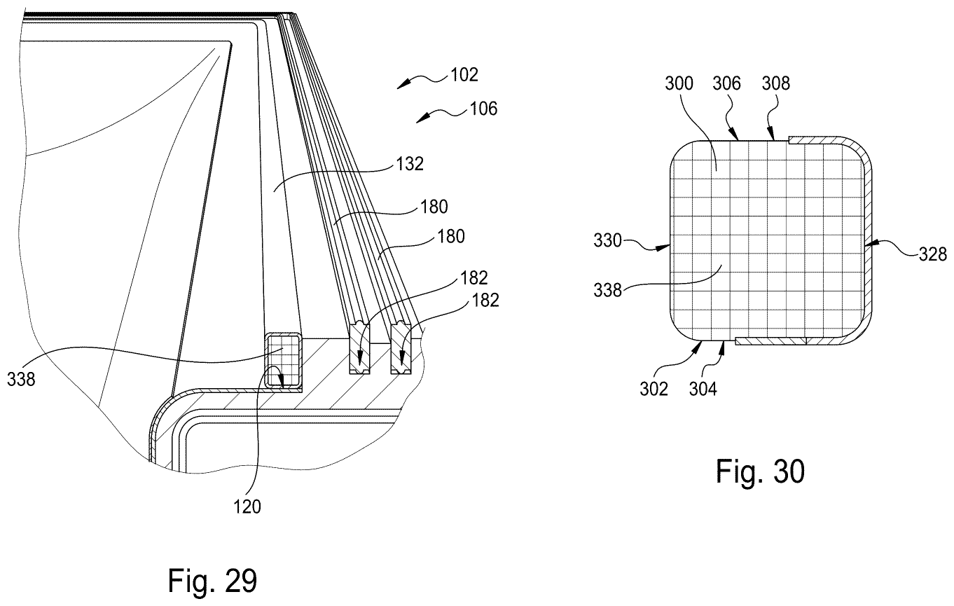

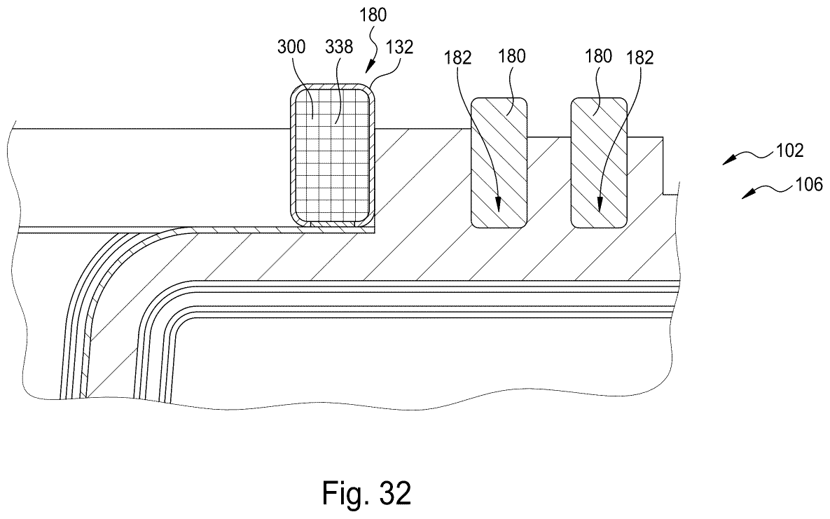

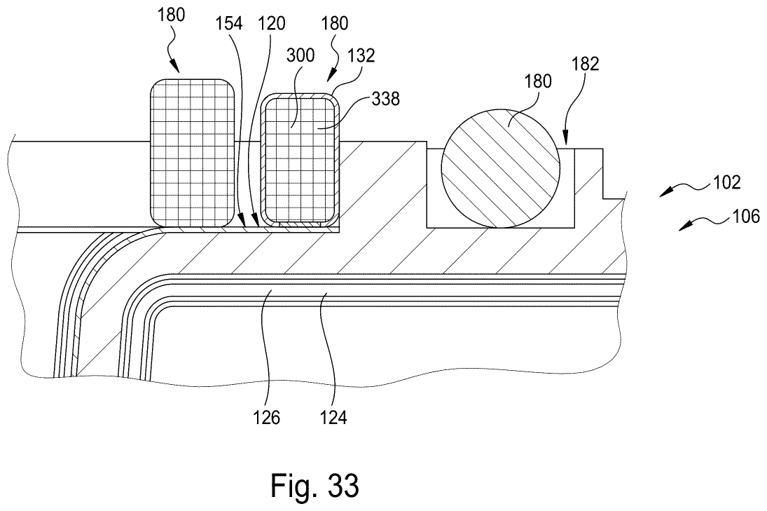

FIGS. 25, 26, 29, and 31 to 33 each illustrate further protective elements 102, each of which comprises differently designed contacting elements 132, in rough simplified illustrations. The protective elements 102 shown therein each include, like the protective elements 102 shown in FIGS. 22 to 24, a seal element 180 and a seal element receptacle 182. At least one of multiple seal elements 180 extends in each case in the seal element receptacle 182 on the protective element 102.

In the protective elements 102 shown in FIGS. 25, 26, 29, and 31 to 33, in each case one of the seal elements 180 includes the contacting element 132 and the carrier 300. The contacting element 132 is arranged in each case on the deformable and/or elastic carrier 300.

It would instead likewise be possible, for example, that the contacting element 132 includes or forms the seal element 180, for example, the seal element 180 could be formed by a metallic spring element functioning as the contact element 132, which has legs elastically deformable in relation to one another, wherein one leg could be able to lie against the device and the other leg could lie against the contacting zone.

FIGS. 28 and 30 each show a contacting element 132, which extends on the carrier 300 on only one side from the inner side 302 and/or protective element side 304 to the outer side 306 and/or device side 308.

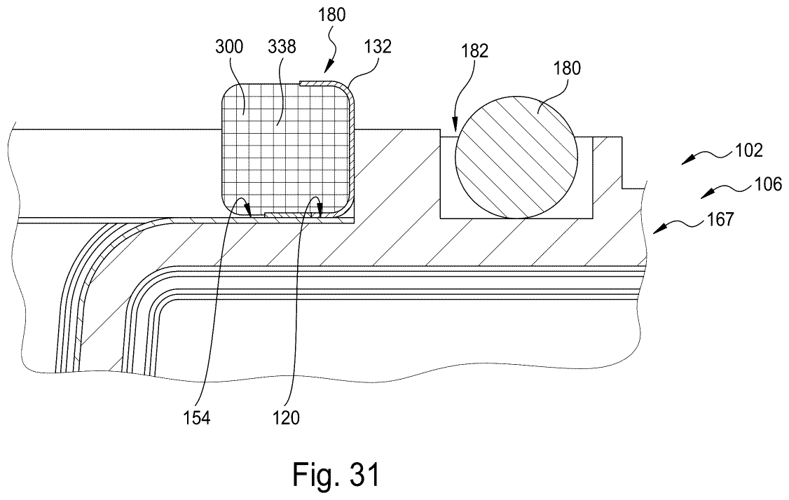

For example, the contacting element 132 can extend on an edge side 328 of the carrier 300, which in an installed state on the protective element 102 can face toward a protective element edge 167, from the inner side 302 and/or protective element side 304 to the outer side 306 and/or device side 308 (FIGS. 30, 31).

Alternatively, the contacting element 132 can extend on an edge-averted side 330 of the carrier 300, which can face away from a protective element edge 167, from the inner side 302 and/or protective element side 300 toward to the outer side 306 and/or device side 308 (FIG. 28 in conjunction with FIG. 31).

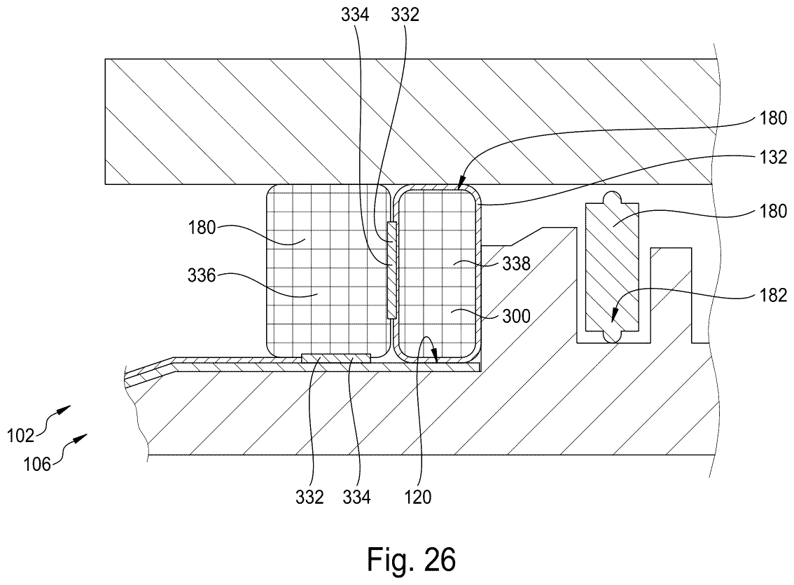

It can be advantageous if the contacting element 132 and/or the carrier 300 is attached in or on the contacting zone 120. For example, the contacting element 132 and/or the carrier 300 can be attached in or on the contacting zone 120 so that an electrical contact of the contacting element 132 with the contacting zone 120 exists or can be established or stabilized. Different options exist for this purpose. A part of these options is indicated in FIGS. 26, 27, 28, 30, 31, 32, and 33.

For example, as shown in each of FIGS. 31 to 33, the contacting element 132 and/or the carrier 300 can be attached in or on the contacting zone 120 via a connecting material 334 arranged in a connecting zone 332. FIGS. 28 and 30 each also provide a connecting material 334 arranged in a connecting zone 332 on the contacting element 132 and/or on the carrier 300 for attachment in or on a contacting zone 120.

Alternatively, the contacting element 132 and/or the carrier 300 can be attached to the contacting zone 120 by means of an auxiliary element 336, which can be, for example, a seal element 180, so that an electrical contact of the contacting element 132 with the contacting zone 120 exists or can be established or stabilized.

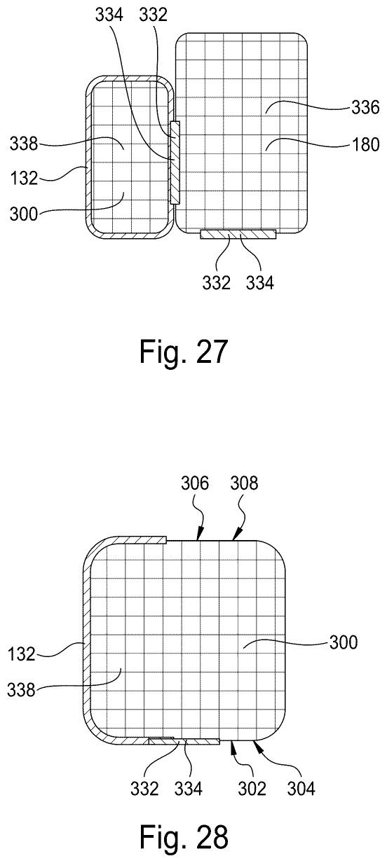

This is indicated in FIGS. 26 and 27. For example, the auxiliary element 336 can be attached to the contacting zone 120 or in another area of the protective element 102 and the contacting element 132 and/or the carrier 300 can be attached to the auxiliary element 336 (FIG. 26). FIG. 27 shows a reversed arrangement of the contacting element 132 arranged on the carrier 300 and the auxiliary element 336 in a non-installed state.

With respect to FIG. 26, it is to be noted that it can be particularly advantageous if in place of the carrier 300 provided with the contacting element 132 and the seal element 180 shown on the left adjacent thereto, a carrier shown in FIG. 28 or a carrier shown in FIG. 30, which is provided with a contacting element 132 and which can also be used as the seal element 180, can be used.

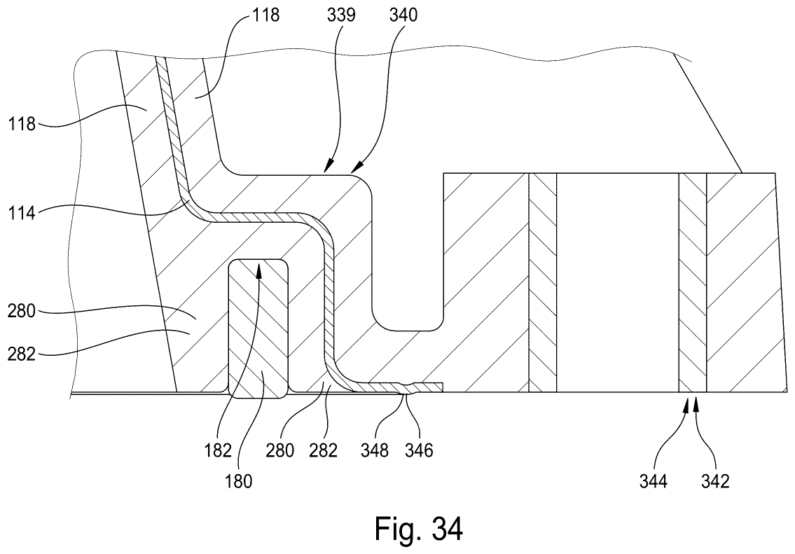

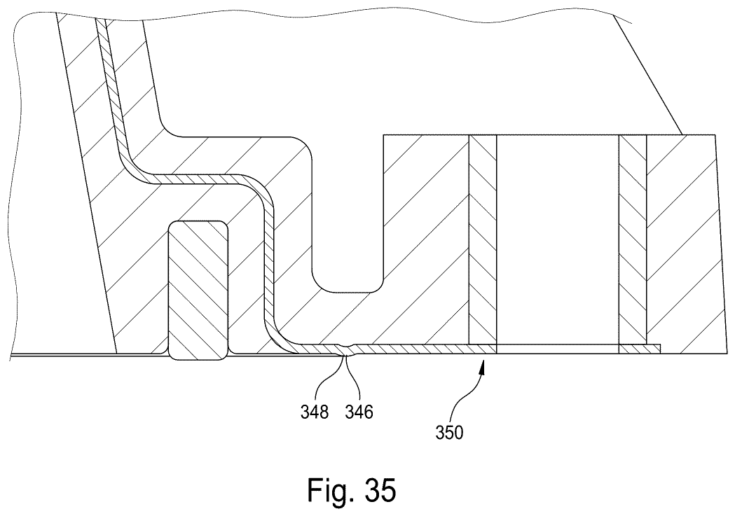

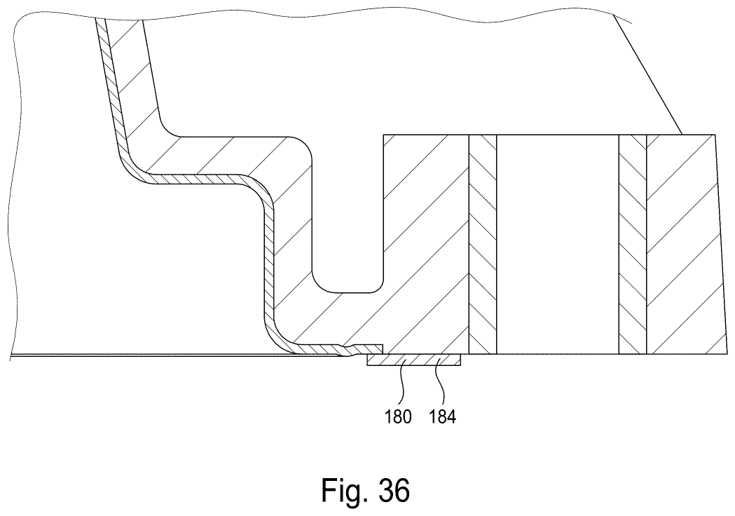

FIGS. 34 to 36 show sectional views of edge areas of protective elements 102. The protective elements 102 shown therein each include a base body 339, for example, a plastic base body 340. The shielding layer 114 extends in the protective elements 102, which are shown in FIGS. 34 and 35, through the base body 339. In the protective element 102 which is shown in FIG. 36, the shielding layer 114 is arranged on the base body 339.

The protective elements 102 shown in FIGS. 34 to 36 each include a coupling auxiliary element 342. The coupling auxiliary element 342 can be, for example, a sleeve 344. A screw or a bolt can be led through the coupling auxiliary element 342.

The protective elements 102 shown in FIGS. 34 to 36 each include a seal element 180.

The protective elements 102 shown in FIGS. 34 and 35 each include a seal element receptacle 182. In the protective elements 102 shown in FIGS. 34 and 35, the seal element 180 is in each case partially accommodated in the seal element receptacle 182.

FIGS. 34 and 35 show that the protective element 102 shown therein includes in each case two positioning and/or alignment elements 280, which are each a positioning and/or alignment projection 282.

The positioning and/or alignment element 280 shown farther to the right is arranged on the contacting zone.

The seal element extends along the two positioning and/or alignment elements 280 in the seal element receptacle 182 located therebetween.

FIGS. 34 and 35 show that the contacting zone can be formed in each case by a raised zone 346, for example, by a fold 348.

The protective element 102 shown in FIG. 35 includes a contact pressure zone 350, in which the shielding layer 114 overlaps the coupling auxiliary element 342.

In place of the seal element 180 and the seal element receptacle 182 shown in FIGS. 34 and 35, the protective element shown in FIG. 36 includes a seal element 180 in the form of a liquid seal 184.

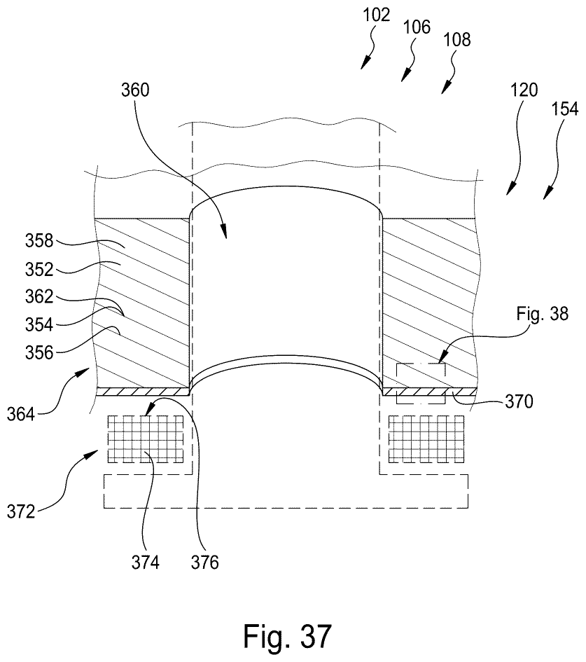

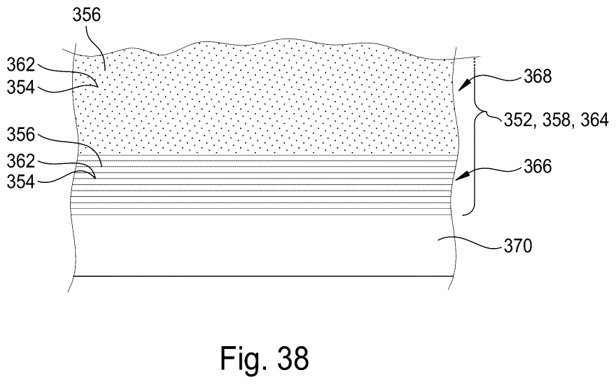

FIG. 37 shows a small detail of a protective element 102 in a perspective sectional view. FIG. 38 shows an enlarged detail of FIG. 37 in a rough simplified schematic view. The section shown therein is a section led through an installation recess 360. A screw, which is shown by dashed lines, or a bolt can be led through the installation recess 360.

The protective element 102 shown in FIG. 37 can be, for example, an underbody protective element 108 and/or a battery housing part 106. A contacting zone 120 which can be, for example, an outer surface contacting zone 154, can be provided laterally offset to the detail shown. This is indicated in FIG. 37 by the reference signs 120 and 154.

For example, one of the protective elements 102 entirely or partially shown or indicated in FIGS. 2, 3, 6, 9, 17, 21, 22, 23, 24, 25, 29, 31, 32, 33, 34, 35, and 36 can include an installation recess 360 and in each case can include therein one or more of the features described here in conjunction with FIG. 37 or 38.

Thus, for example, in the protective element 102 which is shown in FIG. 31, an installation recess 360 shown in FIG. 37 can be provided or formed between the seal element receptacle 182 and the protective element edge 167. The coupling auxiliary element 342 shown in FIGS. 34 to 36 can be seated in an installation recess 360, which can have one or more of the features shown in FIGS. 37 and 38. An installation recess located close to the protective element edge 167 is indicated in each of FIGS. 22 and 23, but is not provided with a reference sign therein in each case.

The protective element 102 shown in FIG. 37 includes a reinforcement zone 352. The reinforcement zone 352 includes reinforcement fibers 354 and a fiber connecting material 356. Reinforcement fibers 354 are connected using the fiber connecting material 356 in the reinforcement zone 352.

The reinforcement zone 352 extends through a suspension zone 358.

The protective element 102 shown in FIG. 37 can be, for example, an underbody protective element 108. It can be installed on a device (not shown) in the suspension zone 358 by means of the installation recess 360 extending through the suspension zone 358 and the screw shown by dashed lines.

Alternatively, it would be possible that a component, for example, a component of a high-voltage battery device, would be able to be attached, for example, installed on the protective element 102, for example, underbody protective element 108, in the suspension zone 358, for example, by means of an installation recess 360 extending through the suspension zone 358 and a screw or a bolt.

However, the reinforcement zone 352 can alternatively or additionally extend in other areas of the protective element 102, which are not shown in FIG. 37. For example, the protective element, as indicated in FIG. 17, for example, can include a side wall 171 and an interior 157, wherein the interior 157 is enclosed by the side wall 171. The reinforcement zone 352 can extend, for example, through at least one section of the side wall 171 or can reinforce the entire side wall 171.

The reinforcement fibers 354 are glass fibers 362 in the protective element 102 shown in FIGS. 37 and 38.

The reinforcement zone 352 includes a fiber laying 358. The fiber laying 358 is a glass fiber laying 364. It is multi-ply, as indicated in FIG. 38. The glass fibers 362 used as the reinforcement fibers 354 are aligned unidirectionally in at least one ply 366 of the reinforcement zone 352.

The glass fibers 362 used as the reinforcement fibers 354 are aligned unidirectionally in at least one further ply 368 of the reinforcement zone 352, wherein the alignment of the glass fibers 362 in the at least one further ply 368 of the reinforcement zone 352 differs from the alignment of the reinforcement fibers 354, for example, the glass fibers 362 in the at least one ply 366 of the reinforcement zone 352. In the one ply 366, the glass fibers 362 extend along the plane of section. In the further ply 368, the glass fibers 362 extend transversely to the plane of section. In particular with regard to the mass proportion of the reinforcement fibers 354, FIG. 38 represents a rough simplification, since a large part of the reinforcement fibers 354 were omitted therein.

The protective element 102 which is shown in FIGS. 37 and 38 includes a sealing layer 370. A section of the sealing layer 370 which is arranged on the reinforcement zone 352 and seals at least one section of the reinforcement zone 352 is shown in the two figures.

The at least one sealed section of the reinforcement zone 352 is a section of the suspension zone 358 which extends around the installation recess 380.

The sealing layer 370 shown therein does not contain reinforcement fibers. It can contain a thermoplastic, such as polypropylene, and/or can be produced from a thermoplastic, such as polypropylene.

### LIST OF REFERENCE SIGNS

100 aluminum component
101 aluminum plate
102 protective element
103 mu-metal
104 reinforcement rib
105 foil
106 battery housing part
107 intermediate layer
108 underbody protective element
109 shielding component
110 insulation layer
111 contact zone
112 housing component
113 shielding zone
114, 115 shielding layer
116 aluminum foil
117 layer composite zone
118 plastic layer
119 protective element surface
120 contacting zone
124 reinforcement layer
125 transmitter
126 fibers
127 source
128 organic plate
129, 131 distance
130 protective layer
132 contacting element
135 sensor
137 receiver
139 holding element
141, 143, 145, 147, 149, 151, 153 area
142 ground
144 carrier structure
146 frame
148 plastic core
150 cover ply
152 cover layer
154 outer surface contacting zone
155 feedthrough zone
156 outer surface
157 interior
159 exterior
161 inverter housing element
163 housing element
165 flange
167 protective element edge
171 side wall
173 wall
180 seal element
181 cable shielding element
182 seal element receptacle
183 conversion device
184 liquid seal
185 inverter
187 electric motor
189 plane of section
191 cable
193 cable strand
195 source
197 depression
199 energy supply system
201 communication system
203 first communication unit
205 second communication unit
207 interface
209 signal
211 connecting device
213 protective element thickness
217, 219 thickness
221 copper band
268 fibers
270 fibrous material
272 compression zone
274 hollow contacting element
276 fabric tube
278 fiber material tube
280 positioning and/or alignment element
282 alignment projection
300 carrier
302 inner side of the carrier
304 protective element side of the carrier
306 outer side of the carrier
308 device side of the carrier
310 electrically conductive material
312 metallic material
314 aluminum
316 first direction
318 extension in the first direction
320 second direction
322 extension in the second direction
324 third direction
326 extension in the third direction
328 edge side of the carrier
330 edge-averted side of the carrier
332 connecting zone
334 connecting material
336 auxiliary element
338 sealing material
339 base body
340 plastic base body
342 coupling auxiliary element
344 sleeve
346 raised zone
348 fold
350 contact pressure zone
352 reinforcement zone
354 reinforcement fibers
356 fiber connecting material
358 suspension zone
360 installation recess
362 glass fibers
364 glass fiber laying
366 ply of the reinforcement zone
368 further ply of the reinforcement zone
370 sealing layer
372 sealing ring
374 sealing material
376 sealing surface

Certain subjects of the invention can be described in more detail by the following sentences:

1. A protective element (102) for improving electromagnetic compatibility, wherein the protective element (102) comprises the following:
a first shielding layer (114) for protection from electric, magnetic, or electromagnetic fields and
a second shielding layer (115) for protection from electric, magnetic, or electromagnetic fields.

2. The protective element (102) according to sentence 1, characterized in that
the protective element (102) comprises the following:
   a shielding zone (113), in which the first and the second shielding layer (114, 115) are spaced apart from one another.

3. The protective element (102) according to one of sentences 1 or 2, characterized in that
an intermediate layer (107) is arranged between the first shielding layer (114) and the second shielding layer (115),
wherein the intermediate layer (107) is preferably arranged in the shielding zone (113) between the first shielding layer (114) and the second shielding layer (115).

4. The protective element (102) according to any one of the preceding sentences, characterized in that
a layer composite zone (117) is present, in which the first and the second shielding layer (114, 115) are connected by means of the intermediate layer (107),
wherein the layer composite zone (117), in which the first and the second shielding layer (114, 115) are connected by means of the intermediate layer (107), is preferably present in the shielding zone (113).

5. The protective element (102) according to any one of the preceding sentences, characterized in that
the shielding layers (114, 115) are electrically conductive.

6. The protective element (102) according to any one of the preceding sentences, characterized in that
at least one of the shielding layers (114, 115), for example, the first shielding layer (114), has a relative permeability μᵣ of at least 10, for example, of at least 5000.

7. The protective element (102) according to any one of the preceding sentences, preferably according to sentence 6,
characterized in that
at least one of the shielding layers (114, 115), for example, the first shielding layer (114), is ferromagnetic.

8. The protective element (102) according to any one of the preceding sentences, preferably according to sentence 6 or 7,
characterized in that
at least one of the shielding layers (114, 115), for example, the first shielding layer (114), contains a mu-metal (103) or is formed from a mu-metal (103).

9. The protective element (102) according to any one of the preceding sentences, preferably according to any one of preceding sentences 1 to 5,
characterized in that
the protective element (102) comprises the following:
   a contact zone (111), in which the first and the second shielding layer (114, 115) are in electrical contact or in which an electrical contact can be established between the first and the second shielding layer (114, 115).

10. The protective element (102) according to any one of the preceding sentences, characterized in that
at least one of the shielding layers (114, 115), for example, at least the second shielding layer (115), contains the following:
   a metallic alloy, wherein the metallic alloy can be, for example, a metallic alloy based on aluminum, copper, iron, or silver;
   a conductive carbon material, wherein the conductive carbon material can contain, for example, carbon fibers or graphite;
   a composite made of a metal and a textile material, preferably a metallically coated textile material, wherein the textile material can preferably be a knitted fabric, a woven fabric, a laying, a knit, a mesh, or a nonwoven material, for example, a composite made of an aluminum foil and a PET nonwoven material;
   a foil, preferably a metal foil, for example, an aluminum foil;
   an expanded metal;
   a regular fibrous planar formation, wherein the regular fibrous planar formation can be, for example, a knitted fabric, a woven fabric, a laying, a knit, or a mesh; and/or
   an irregular fibrous planar formation, wherein the irregular fibrous planar formation can be, for example, a nonwoven material.

11. The protective element (102) according to any one of the preceding sentences, characterized in that
at least one of the shielding layers (114, 115), for example, at least the second shielding layer (115), is provided as
   a foil (105),
   a plate,
   a regular fibrous planar formation, wherein the regular fibrous planar formation can be, for example, a woven fabric, a knit, or a mesh, or as
   an irregular fibrous planar formation, wherein the irregular fibrous planar formation can be, for example, a nonwoven material.

12. The protective element (102) according to any one of the preceding sentences, characterized in that
at least one of the shielding layers (114, 115), for example, at least the second shielding layer (115), is selected among:
   an aluminum foil (116),
   an aluminum mesh,
   a stainless-steel mesh,
   a bronze mesh,
   a copper mesh,
   a plastic nonwoven material (for example, PET nonwoven material) having applied aluminum film,
   a plastic nonwoven material (for example, PET nonwoven material), which is coated on one side using copper,
   a carbon fiber-containing unidirectional tape,
   a nonwoven material made of recycled carbon fibers,
   a graphite film, and
   a polymer (for example, polypropylene) in combination with an aluminum mesh.

13. The protective element (102) according to any one of the preceding sentences, characterized in that
at least one of the shielding layers (114, 115), for example, at least the second shielding layer (115), contains a metal, for example, aluminum, copper, iron, and/or silver,
wherein it is preferred if at least one of the shielding layers (114, 115), for example, at least the second shielding layer (115), contains aluminum.

14. The protective element (102) according to any one of the preceding sentences, characterized in that
a thickness of at least one of the shielding layers (114, 115), for example, a thickness of the second shielding layer (115) is at most 3 mm, for example, 0.001 to 0.7 mm.

15. The protective element (102) according to any one of the preceding sentences, characterized in that
at least one of the shielding layers (114, 115), for example, at least the second shielding layer (115), is an aluminum foil (116) or an aluminum plate.

16. The protective element (102) according to any one of sentences 10 to 15, characterized in that the foil (105), metal foil, or aluminum foil (116) is attached by means of an adhesion promoter to an adjacent layer, for example, intermediate layer (107).

17. The protective element (102) according to any one of the preceding sentences, characterized in that
at least one of the shielding layers (114, 115) is formed on a surface of a substrate layer,
wherein the at least one of the shielding layers (114, 115) is preferably formed on the surface by deposition from a surrounding medium,
wherein the at least one of the shielding layers (114, 115) can be vapor deposited, for example, on the surface.

18. The protective element (102) according to any one of the preceding sentences, characterized in that the protective element (102) comprises the following:
a protective element surface (119) for attaching the protective element to a device that can be interfered with by electric, magnetic, or electromagnetic fields or to a source of electric, magnetic, or electromagnetic fields.

19. An energy supply system (199), for example, for an entirely or partially electrically driven motor vehicle,
wherein the energy supply system (199) comprises the following:
   at least two conversion devices (183),
   a connecting device (211), which connects the at least two conversion devices (183), and
   at least one protective element (102) according to any one of sentences 1 to 18 on at least one of the at least two conversion devices (183) and/or on the connecting device (211) to protect the surroundings of the energy supply system (199) from electric, magnetic, or electromagnetic fields,
   wherein it is preferred if, to protect the surroundings, at least one of the at least two conversion devices (183) and/or the connecting device (211) is entirely or partially accommodated in an interior (157) or in a depression (197) of the at least one protective element (102).

20. A communication system (201), for example, for an entirely or partially electrically driven motor vehicle,
wherein the communication system (201) comprises the following:
   a first communication unit (203), which includes an interface (207) for emitting an electric, magnetic, or electromagnetic signal (209),
   a second communication unit (205), which includes an interface (207) for receiving the electric, magnetic, or electromagnetic signal (209) of the first communication unit, and
   at least one protective element (102) according to any one of sentences 1 to 18 to protect at least one of the communication units (203, 205) from electric, magnetic, or electromagnetic fields,
   wherein it is preferred if, to protect the at least one of the communication units (203, 205) from electric, magnetic, or electromagnetic fields, the at least one of the communication units (203, 205) is entirely or partially accommodated in an interior (157) or in a depression (197) of the protective element (102).

21. A motor vehicle, for example, an entirely or partially electrically driven motor vehicle, wherein the motor vehicle comprises the following:
a source (195) of electric, magnetic, or electromagnetic fields, wherein the source (195) can advantageously be a conversion device (183) of an energy supply system (199) of the motor vehicle, for example, an electric motor (187) or an inverter (185), or a connecting device (211), wherein the connecting device (211) can connect two conversion devices (183) to one another,
a device that can be interfered with by electric, magnetic, or electromagnetic fields, wherein the device that can be interfered with by electric, magnetic, or electromagnetic fields can be or comprise, for example, a communication unit (203, 205) of the motor vehicle, and
at least one protective element (102) according to any one of sentences 1 to 18, wherein the protective element (102) is entirely or partially arranged between the source (195) and the device that can be interfered with by the electric, magnetic, or electromagnetic fields.

1. A protective element for improving electromagnetic compatibility, the protective element comprising:
a shielding layer for protection from electric, magnetic, and/or electromagnetic fields.

2. The protective element as claimed in claim 1, wherein
the protective element comprises a contacting zone.

3. The protective element as claimed in claim 1, further comprising:
a second shielding layer for protection from electric, magnetic, and/or
electromagnetic fields, wherein
the shielding layer is a first shielding layer.

4. The protective element as claimed in claim 2, wherein
an electrical contact is capable of being established by means of the contacting zone between the shielding layer and a device, on which the protective element is capable of being attached or installed,
an electrical contact is capable of being established by means of the contacting zone between the shielding layer of the protective element and/or at least one of the shielding layers of the protective element and a device, on which the protective element is capable of being attached or installed,
the contacting zone is a surface of the shielding layer and/or a surface of at least one of the shielding layers;
and/or
the contacting zone is located on a surface of the shielding layer and/or on a surface of at least one of the shielding layers;
and/or
the contacting zone is an outer surface contacting zone, wherein the outer surface contacting zone is formed on an outer surface of the shielding layer and/or on an outer surface of at least one of the shielding layers.

5. The protective element as claimed in claim 2,
wherein
the protective element comprises a contacting element, and
wherein
an electrical contact is capable of being established or stabilized by means of the contacting element between the contacting zone and the device,
and/or
an electrical contact bridged by the contacting element is capable of being established between the contacting zone and the device, wherein one surface of the contacting element is in electrically conductive contact with the contacting zone, and a further surface of the contacting element is capable of being brought into electrically conductive contact with the device, wherein the contacting element is electrically conductive.

6. The protective element as claimed in claim 5,
wherein
the contacting element is deformable and/or elastic;
the contacting element is arranged on a carrier, wherein the carrier is deformable and/or elastic;
the contacting element extends in at least one section of a carrier from an inner side and/or protective element side of the carrier, which is facing toward the contacting zone, up to an outer side and/or device side of the carrier, which is facing away from the contacting zone;
the contacting element contains an electrically conductive material or is produced therefrom, and/or the electrically conductive material is a metallic material and/or aluminum;
the contacting element extends in at least one section of the carrier on the carrier on only one side, and/or
on an edge side of the carrier, which can be facing toward a protective element edge, or
on an edge-averted side of the carrier, which can be facing away from a protective element edge,
from the inner side and/or protective element side to the outer side and/or device side.

7. The protective element as claimed in claim 1,
wherein
the protective element includes a seal element and/or includes a seal element receptacle, in which a seal element is capable of being entirely or partially accommodated,
wherein if the protective element includes the seal element and the seal element receptacle, wherein if the seal element is entirely or partially accommodated in the seal element receptacle and/or extends in the seal element receptacle on the protective element;
and/or
the protective element includes a seal element, which is a liquid seal.

8. The protective element as claimed in claim 6, wherein
the seal element includes the contacting element and/or the carrier;
and/or
the carrier is deformable and/or elastic, wherein if the contact element is arranged on the deformable and/or elastic carrier;
and/or
the contacting element includes or forms the seal element.

9. The protective element as claimed in claim 5,
wherein
the contacting element and/or the carrier is attached in or on the contacting zone;
the contacting element and/or the carrier is attached in or on the contacting zone via a connecting material arranged in a connecting zone;
the contacting element and/or the carrier is attached to the contacting zone by means of an auxiliary element or a seal element, whereby an electrical contact of the contacting element with the contacting zone exists or is capable of being established or stabilized, or the auxiliary element is attached to the contacting zone or in another area of the protective element and the contacting element and/or the carrier is attached to the auxiliary element,
wherein if
the auxiliary element is attached to the contacting zone or in the other area of the protective element via a connecting material arranged in a connecting zone;
and/or
the contacting element and/or the carrier is attached to the auxiliary element via a connecting material arranged in a connecting zone.

10. The protective element as claimed in claim 6, wherein
the protective element includes at least two seal elements, and one of the seal elements is arranged closer to a protective element edge than another of the seal elements.

11. The protective element as claimed in claim 6, wherein
the carrier and/or the seal element and/or at least one of the seal elements contains or is produced from at least one of the following:
an elastic sealing material, and/or
a natural or synthetic rubber, and/or
an ethylene-propylene-diene rubber, and/or
a silicone rubber, and/or
a fluorine rubber, and/or
a polyurethane, and/or
an ethylene tetrafluoroethylene
or consists thereof.

12. The protective element as claimed in claim 1,
wherein
the protective element includes a positioning and/or alignment element or a positioning and/or alignment projection;
the protective element includes a positioning and/or alignment element, wherein
at least one section of the positioning and/or alignment element is arranged on at least one section of the contacting zone;
and/or
at least one section of the carrier and/or the seal element and/or at least one of the seal elements and/or the contacting element and/or the connecting zone extends along at least one section of the positioning and/or alignment element; or
the protective element includes a plastic base body, wherein
the shielding layer is arranged on the plastic base body and/or extends through the plastic base body,
and/or
at least one of the shielding layers is arranged on the plastic base body and/or extends through the plastic base body;
or
the protective element includes a reinforcement zone,
wherein the reinforcement zone includes reinforcement fibers and a fiber connecting material,
wherein at least a part of the reinforcement fibers are connected using the fiber connection material in the reinforcement zone;
or
the protective element is an underbody protective element and/or a battery housing part.

13. The protective element as claimed in claim 12,
wherein
the reinforcement zone is a suspension zone or extends into a suspension zone or through a suspension zone;
or
the reinforcement zone is a suspension zone or extends into a suspension zone or through a suspension zone; and
the protective element and/or underbody protective element and/or battery housing part can be attached to the device, or, installed, in the suspension zone, or, by means of an installation recess extending through the suspension zone and a screw or a bolt;
and/or
a component, or, a component of a high-voltage battery device, capable of being attached, or, installed on the protective element and/or underbody protective element and/or battery housing part in the suspension zone, or, by means of an installation recess extending through the suspension zone and a screw or a bolt.

14. The protective element as claimed in claim 12,
wherein
the protective element and/or underbody protective element and/or battery housing part includes a side wall and an interior, wherein the interior is entirely or partially enclosed by the side wall,
wherein the reinforcement zone extends through at least one section of the side wall,
a mass proportion of the reinforcement fibers in the reinforcement zone is at least 70%, or, at least 77.5%;
the reinforcement fibers are glass fibers
the reinforcement zone includes a fiber laying, or, a glass fiber laying, and/or the reinforcement fibers, or, the glass fibers are unidirectionally aligned in at least one ply of the reinforcement zone.

15. The protective element as claimed in claim 14,
wherein
the reinforcement fibers or the glass fibers are unidirectionally aligned in at least one further ply of the reinforcement zone, wherein the alignment of the reinforcement fibers or the glass fibers in the at least one further ply of the reinforcement zone differs from the alignment of the reinforcement fibers or the glass fibers in the at least one ply of the reinforcement zone.

16. The protective element as claimed in claim 15,
wherein
the protective element includes a sealing layer,
the protective element includes a sealing layer wherein at least one section of the sealing layer is arranged on the reinforcement zone and seals at least one section of the reinforcement zone.

17. The protective element as claimed in claim 16,
wherein
the sealing layer does not contain reinforcement fibers or a mass proportion of the reinforcement fibers in the sealing layer is less than the mass proportion of the reinforcement fibers in the reinforcement zone.

18. The protective element as claimed in claim 3,
wherein
the protective element comprises the following:
a shielding zone, in which the first and the second shielding layer are spaced apart from one another; and/or
an intermediate layer which is arranged between the first shielding layer and the second shielding layer; and/or
an intermediate layer which is arranged in the shielding zone between the first shielding layer and the second shielding layer; and/or
a layer composite zone is present, in which the first and the second shielding layer are connected by means of the intermediate layer; and/or
wherein the layer composite zone, in which the first and the second shielding layer are connected by means of the intermediate layer, is present in the shielding zone.

19. The protective element as claimed in claim 1,
wherein
the shielding layer is electrically conductive and/or the shielding layers are electrically conductive;
the shielding layer and/or at least one of the shielding layers and/or the first shielding layer has a relative permeability μᵣ of at least 10 or of at least 5000;
the shielding layer and/or at least one of the shielding layers and/or the first shielding layer is ferromagnetic;
the shielding layer and/or at least one of the shielding layers and/or the first shielding layer contains a mu-metal or is formed from a mu-metal.

20. The protective element as claimed in claim 3,
wherein
the protective element comprises the following:
a contact zone, in which the first and the second shielding layer are in electrical contact or in which an electrical contact can be established between the first and the second shielding layer.

21. The protective element as claimed in claim 1,
wherein
the shielding layer and/or at least one of the shielding layers and/or at least the second shielding layer contains the following:
a metallic alloy or a metallic alloy based on aluminum, copper, iron, or silver;
a conductive carbon material or a conductive carbon material which contains carbon fibers or graphite;
a composite made of a metal and a textile material or a metallically coated textile material, or wherein the textile material is a knitted fabric, a woven fabric, a laying, a knit, a mesh, a nonwoven material, or a composite made of an aluminum foil and a PET nonwoven material;
a foil or a metal foil or an aluminum foil;
an expanded metal;
a regular fibrous planar formation, wherein the regular fibrous planar formation is a knitted fabric, a woven fabric, a laying, a knit, or a mesh; and/or
an irregular fibrous planar formation, wherein the irregular fibrous planar formation is a nonwoven material;
or
the shielding layer and/or at least one of the shielding layers and/or at least the second shielding layer is provided as
a foil,
a plate,
a regular fibrous planar formation or a woven fabric, a knit or a mesh; and/or
an irregular fibrous planar formation or a nonwoven material;
or
the shielding layer and/or at least one of the shielding layers and/or at least the second shielding layer is selected among:
an aluminum foil,
an aluminum mesh,
a stainless-steel mesh,
a bronze mesh,
a copper mesh,
a plastic nonwoven material or PET nonwoven material, wherein the plastic nonwoven material or PET nonwoven material has applied aluminum film,
a plastic nonwoven material or PET nonwoven material, wherein the plastic nonwoven material or PET nonwoven material is coated on one side using copper,
a carbon fiber-containing unidirectional tape,
a nonwoven material made of recycled carbon fibers,
a graphite film, and
a polymer or polypropylene in combination with an aluminum mesh;
or
the shielding layer and/or at least one of the shielding layers and/or at least the second shielding layer, contains a metal, aluminum, copper, iron, and/or silver;
or
a thickness of the shielding layer and/or a thickness of at least one of the shielding layers and/or a thickness of the second shielding layer, is at most 3 mm or 0.001 to 0.7 mm
or
the shielding layer and/or at least one of the shielding layers and/or at least the second shielding layer is an aluminum foil or an aluminum plate;
or
the shielding layer and/or at least one of the shielding layers is formed on a surface of a substrate layer by deposition from a surrounding medium, or wherein the shielding layer and/or the at least one of the shielding layers is vapor deposited on the surface.

22. The protective element as claimed in claim 21,
wherein
the foil, metal foil, or aluminum foil is attached by means of an adhesion promoter to an adjacent layer or intermediate layer.

23. An energy supply system for an entirely or partially electrically driven motor vehicle, wherein the energy supply system comprising:
at least two conversion devices,
a connecting device, which connects the at least two conversion devices, and
at least said protective element as claimed in claim 1 on at least one of the at least two conversion devices and/or on the connecting device to protect the surroundings of the energy supply system from electric, magnetic, or electromagnetic fields,
wherein at least one of the at least two conversion devices and/or the connecting device is entirely or partially accommodated in an interior or in a depression of the at least one protective element.

24. A communication system for an entirely or partially electrically driven motor vehicle, wherein the communication system comprising:
a first communication unit, which includes an interface for emitting an electric, magnetic, or electromagnetic signal,
a second communication unit, which includes an interface for receiving the electric, magnetic, or electromagnetic signal of the first communication unit, and
at least said protective element as claimed in claim 1 to protect at least one of the communication units from electric, magnetic, or electromagnetic fields, and is entirely or partially accommodated in an interior or in a depression of the protective element.

25. A motor vehicle for an entirely or partially electrically driven motor vehicle, wherein the motor vehicle comprising:
a source of electric, magnetic, or electromagnetic fields, wherein the source is a conversion device of an energy supply system of the motor vehicle, or, an electric motor or an inverter, or a connecting device, wherein the connecting device can connect two conversion devices to one another,
a device that can be interfered with by electric, magnetic, or electromagnetic fields, wherein the device that can be interfered with by electric, magnetic, or electromagnetic fields can be or comprise a communication unit of the motor vehicle, and
at said protective element as claimed in claim 1, wherein the protective element is entirely or partially arranged between the source and the device that can be interfered with by the electric, magnetic, or electromagnetic fields.

26. A method for producing said protective element as claimed in claim 1, wherein sealing of a surface area of a base body of the protective element is carried out by applying a plastic-containing sealing material.

27. The method as claimed in claim 26,
wherein
the base body is formed in a molding tool from multiple starting materials flatly layered on one another partially or completely overlapping, or wherein at least one of the starting materials is fiber-reinforced,
wherein the plastic-containing sealing material is introduced into the molding tool and/or the sealing of the surface area in the molding tool by the plastic-containing sealing material is carried out directly during the production of the fiber-reinforced base body;
the base body is a fiber-reinforced base body and the surface area is porous and/or a part of the reinforcement fibers of the base body extend to the surface area of the base body;
the plastic-containing sealing material is a plastic film and/or contains reinforcement fibers.
